(19) United States
(12) Patent Application Publication
(10) Pub. No.: US 2015/0004327 A1
(43) Pub. Date: Jan. 1, 2015

(54) CONDUCTIVE MEMBER AND METHOD FOR MANUFACTURING SAME

(71) Applicant: FUJIFILM Corporation, Tokyo (JP)

(72) Inventors: Kenichi YAMAMOTO, Ashigarakami-gun (JP); Takahiro HAYASHI, Ashigarakami-gun (JP); Satoshi KUNIYASU, Ashigarakami-gun (JP)

(73) Assignee: FUJIFILM Corporation, Tokyo (JP)

(21) Appl. No.: 14/489,939

(22) Filed: Sep. 18, 2014

Related U.S. Application Data
(63) Continuation of application No. PCT/JP2013/055319, filed on Feb. 28, 2013.

(30) Foreign Application Priority Data
Mar. 23, 2012 (JP) 2012-068215
Jul. 26, 2012 (JP) 2012-165774

(51) Int. Cl. G06F 3/041; H05K 3/46; H05K 3/06; H05K 1/11

(52) U.S. Cl. CPC G06F 3/041; H05K 1/11; H05K 3/4644; H05K 3/06; H05K 2203/095; H05K 2203/097; H05K 2203/1163; H05K 2203/122
USPC 427/535; 174/253; 349/12; 427/58; 427/126.1; 427/553

(57) ABSTRACT

A conductive member includes a substrate, conductive layers that are provided on both surfaces of the substrate, and contain a conductive fiber having an average minor axis length of 150 nm or less and a matrix, and intermediate layers that are provided between the substrate and the conductive layers, and contain a compound having a functional group capable of interacting with the conductive fiber, and, when surface resistance values of the two conductive layers are represented by A and B respectively, and an A value is equal to or greater than a B value, A/B is in a range of 1.0 to 1.2.

### CROSS-REFERENCE TO RELATED APPLICATIONS

This application is a Continuation of PCT International Application No. PCT/JP2013/055319 filed on Feb. 28, 2013, which claims priority under 35 U.S.C §119(a) to Japanese Patent Application No. 2012-165774 filed on Jul. 26, 2012 and Japanese Patent Application No. 2012-068215 filed on Mar. 23, 2012. Each of the above application(s) is hereby expressly incorporated by reference, in its entirety, into the present application.

### BACKGROUND OF THE INVENTION

1. Field of the Invention

The present invention relates to a conductive member and a method for manufacturing the same.

2. Description of the Related Art

Currently, there are a number of known input devices for carrying out operations in a computer system. Among those input devices, recently, a touch panel that is easily operatable and versatile has been widely distributed. In the case of a touch panel, a user can make a desired selection or move the cursor by simply touching the display screen using a finger or a stylus.

The above-described touch panel is configured to include a pair of electrodes (for example, refer to paragraphs 0063 to 0065 and FIG. 10 in JP2007-533044T and paragraph 0044 and FIG. 5 in JP2011-102003A). Therefore, the touch panel is produced using a method including a step in which a conductive member including a conductive layer is used, two conductive elements processed to form a pattern made up of a conductive region and a non-conductive region in the conductive layer are prepared, and the two conductive elements are attached or laminated and then fixed to a surface of an insulating substrate such as a glass sheet or a plastic sheet (hereinafter, this step of “attaching or laminating and then fixing” will also be referred to as the “overlaying” step), thereby obtaining a pair of electrodes.

Recently, there has been a proposal regarding a member having a conductive layer including a conductive fiber such as metal nanowires as the above-described conductive member (for example, refer to JP2009-505358T). This conductive member includes a substrate and a conductive layer including a plurality of metal nanowires on a surface of the substrate. Even in a case in which the above-described conductive member is used, the above-described overlaying step becomes required to produce a touch panel.

However, a touch panel produced through the above-described overlaying step essentially requires two substrates, and thus becomes thick.

In addition, an adjustment step of combining the surface resistance values of the conductive region in the respective patterned conductive layers of the two conductive elements forming the pair is required, and thus the overlaying step becomes necessary, and therefore the number of manufacturing steps is increased accordingly, which causes an increase in the manufacturing cost of the touch panel.

Meanwhile, a method is also known in which a conductive member having conductive layers on the front and back surfaces of a substrate is manufactured using a method for forming the conductive layers including a conductive fiber on the front and back surfaces of the substrate at the same time. For example, a method is known in which a thin film of a dispersion liquid containing a carbon nanotube and a surfactant is formed, and a substrate is relatively moved so as to intersect the thin film, thereby forming conductive layers including the carbon nanotube on the front and back surfaces of the substrate (for example, refer to JP2009-292664A).

### SUMMARY OF THE INVENTION

However, in the conductive member manufactured using the above-described method, the conductive property is anisotropic, it is necessary to reciprocate the substrate 50 times or more to supply a conductivity of 200 Ω/square or less such that the coat thickness significantly varies, and it is difficult to set the ratio between the surface resistance value of the conductive layer formed on the front surface and the surface resistance value of the conductive layer formed on the back surface to 1.2 or less. In addition, since the adhering force between the substrate and the conductive layer is weak, it is necessary to pay careful attention when handling the conductive member, and thus it is difficult to manufacture a conductive member having a defect-free conductive layer even when careful attention is paid. Furthermore, this manufacturing method requires the preparation of a special coating apparatus.

The invention relates to a conductive film containing a conductive fiber, and an object of the invention is to provide a conductive member which, for example, in a case in which a touch panel is manufactured, allows the formation of conductive layers on both surfaces of a substrate so that a thin pair of electrodes can be produced, removes the necessity of the overlaying step of two conductive members so as to decrease the cost, has similar surface resistance values at both surfaces of the conductive layer so that a great effort is not required to set an integrated circuit (IC) on each surface, has desired functions exhibited on both surfaces, and has a strong adhering force between the conductive layer and the substrate.

Furthermore, it is another object of the invention to provide a method for manufacturing a conductive member capable of manufacturing the above-described conductive member using an ordinary coating apparatus.

The invention achieving the above-described objects is as described below.

<1> A conductive member including: a substrate; conductive layers being provided on both surfaces of the substrate, and containing a conductive fiber having an average minor axis length of 150 nm or less and a matrix; and intermediate layers being provided between the substrate and the conductive layers, and containing a compound having a functional group capable of interacting with the conductive fiber, wherein, when surface resistance values of the two conductive layers are represented by A and B respectively, and an A value is equal to or greater than a B value, A/B is in a range of 1.0 to 1.2.

<2> The conductive member according to <1>, in which the conductive fiber is a nanowire containing silver.

<3> The conductive member according to <1> or <2>, in which the average minor axis length of the conductive fiber is 30 nm or less.

<4> The conductive member according to any one of <1> to <3>, in which the matrix contains at least one selected from the group consisting of organic polymers, substances configured by including a three-dimensional crosslinking structure having a bond represented by the following general formula (I), and photoresist compositions,

-M¹-O-M¹- (I)

in the general formula (I), M¹ represents an element selected from the group consisting of Si, Ti, Zr, and Al.

<5> The conductive member according to any one of <1> to <4>, in which the matrix is configured by including a three-dimensional crosslinking structure having a bond represented by the following general formula (I),

-M¹-O-M¹- (I)

in the general formula (I), M¹ represents an element selected from the group consisting of Si, Ti, Zr, and Al.

<6> The conductive member according to any one of <1> to <5>, in which the intermediate layers contain a compound having an amino group or an epoxy group.

<7> The conductive member according to any one of <1> to <6>, in which at least one of the two conductive layers provided on both surfaces of the substrate are configured by including a conductive region and a non-conductive region, and at least the conductive region contains the conductive fiber.

<8> The conductive member according to any one of <1> to <7>, in which the two conductive layers provided on both surfaces of the substrate are configured by including a conductive region and a non-conductive region respectively, and, when surface resistance values of the two conductive regions provided on both surfaces are represented by A and B respectively, and an A value is equal to or greater than a B value, A/B is in a range of 1.0 to 1.2.

<9> A method for manufacturing a conductive member, including:

forming a first intermediate layer on a first surface of a substrate (one face of a substrate) by applying a coating fluid for forming an intermediate layer containing a compound having a functional group capable of interacting with a conductive fiber to form a coated film, and drying the coated film;

forming a first conductive layer on the first intermediate layer by applying a coating fluid for forming a conductive layer containing a conductive fiber having an average minor axis length of 150 nm or less and at least one selected from the group consisting of organic polymers and photoresist compositions to form a coated film, and drying the coated film through heating;

forming a second intermediate layer on a second surface of the substrate (the other face of the substrate) by applying a coating fluid for forming an intermediate layer containing a compound having a functional group capable of interacting with a conductive fiber to form a coated film, and drying the coated film; and

forming a second conductive layer on the second intermediate layer by applying a coating fluid for forming a conductive layer containing a conductive fiber having an average minor axis length of 150 nm or less and at least one selected from the group consisting of organic polymers and photoresist compositions to form a coated film, and drying the coated film through heating,

in which, when surface resistance values of the first conductive layer and the second conductive layer are represented by A and B respectively, and an A value is equal to or greater than a B value, A/B is in a range of 1.0 to 1.2.

<10> A method for manufacturing a conductive member, including:

forming a first intermediate layer on a first surface of a substrate by applying a coating fluid for forming an intermediate layer containing a compound having a functional group capable of interacting with a conductive fiber to form a coated film, and drying the coated film;

forming a first conductive layer on the first intermediate layer by applying a coating fluid for forming a conductive layer containing a conductive fiber having an average minor axis length of 150 nm or less and at least one alkoxide compound of an element selected from the group consisting of Si, Ti, Zr, and Al to form a coated film, hydrolyzing, and polycondensing the alkoxide compound in the coated film through heating to form a three-dimensional crosslinking structure having a bond represented by the following general formula (I) in the coated film,

forming a second intermediate layer on a second surface of the substrate by applying a coating fluid for forming an intermediate layer containing a compound having a functional group capable of interacting with a conductive fiber to form a coated film, and drying the coated film; and

forming a second conductive layer on the second intermediate layer by applying a coating fluid for forming a conductive layer containing a conductive fiber having an average minor axis length of 150 nm or less and at least one alkoxide compound of an element selected from the group consisting of Si, Ti, Zr, and Al to form a coated film, hydrolyzing and polycondensing the alkoxide compound in the coated film through heating to form a three-dimensional crosslinking structure having the bond represented by the following general formula (I) in the coated film;

in which, when surface resistance values of the first conductive layer and the second conductive layer are represented by A and B respectively, and an A value is equal to or greater than a B value, A/B is in a range of 1.0 to 1.2,

-M¹-O-M¹- (I)

in the general formula (I), M¹ represents an element selected from the group consisting of Si, Ti, Zr, and Al.

<11> The method for manufacturing a conductive member according to <9> or <10>, including: carrying out a surface treatment on the first surface and the second surface of the substrate before forming the first intermediate layer.

<12> The method for manufacturing a conductive member according to <11>, in which at least one of a condition that a temperature of the coated film when the coated film is dried in forming the first intermediate layer is a temperature lower than a temperature of the coated film when the coated film is dried in forming the second intermediate layer by 20° C. or more and a condition that a temperature of the coated film during the heating in forming the first conductive layer is a temperature lower than a temperature of the coated film during the heating in forming the second conductive layer by 20° C. or more is satisfied.

<13> The method for manufacturing a conductive member according to <11> or <12>, in which at least one of a condition that a temperature of the coated film when the coated film is dried in forming the first intermediate layer is a temperature lower than a temperature of the coated film when the coated film is dried in forming the second intermediate layer by 40° C. or more and a condition that a temperature of the coated film during the heating in forming the first conductive layer is a temperature lower than a temperature of the coated film during the heating in forming the second conductive layer by 40° C. or more is satisfied.

<14> The method for manufacturing a conductive member according to any one of <11> to <13>, in which a solid content application amount of the coating fluid for forming an intermediate layer in forming the second intermediate layer is in a range of two to three times of a solid content application amount of the coating fluid for forming the intermediate layer in forming the first intermediate layer.

<15> The method for manufacturing a conductive member according to any one of <11> to <14>, in which a solid content application amount of the coating fluid for forming a conductive layer in forming the second intermediate layer is in a range of 1.25 times to 1.5 times of a solid content application amount of the coating fluid for forming a conductive layer in forming the first intermediate layer.

<16> The method for manufacturing a conductive member according to any one of <11> to <15>, in which the surface treatment is a corona discharging treatment, a plasma treatment, a glow treatment, or an ultraviolet ozone treatment, and a treatment amount for treating the second surface of the substrate is in a range of two to six times of a treatment amount for treating the first surface of the substrate being surface-treated.

<17> The method for manufacturing a conductive member according to any one of <9> to <16>, further including: forming a conductive region and a non-conductive region in at least one of the first conductive layer and the second conductive layer.

<18> A touch panel comprising: the conductive member according to any one of <1> to <8> or a conductive member manufactured using the method for manufacturing a conductive member according to any one of <9> to <17>, in which a thickness of the conductive member is in a range of 30 μm to 200 μm.

According to the invention, it is possible to produce a thin pair of electrodes by forming conductive layers on both surfaces of a substrate. Therefore, it is considered that, for example, in a case in which a touch panel is manufactured, the overlaying step of two conductive members becomes unnecessary, and thus it is possible to suppress the cost at a low level. In addition, the conductive member of the invention has similar surface resistance values at both surfaces of the conductive layer so that desired functions are exhibited on both surfaces. Furthermore, a conductive member having a strong adhering force between the conductive layer and the substrate is provided.

Furthermore, according to the invention, a method for manufacturing a conductive member capable of manufacturing the conductive member using an ordinary coating apparatus is provided.

### BRIEF DESCRIPTION OF THE DRAWING

FIG. 1A and FIG. 1B illustrate schematic cross-sectional views of individual conductive members according to Example 1 and Comparative Example 1 immediately after individual steps in a process for manufacturing the conductive members.

### DESCRIPTION OF THE PREFERRED EMBODIMENTS

Hereinafter, the invention will be described based on a typical embodiment of the invention, but the invention is not limited to the described embodiment within the scope of the purpose of the invention.

In the present specification, a terminology of “light” is used as a concept including not only visible light rays but also high-energy rays such as ultraviolet rays, X-rays, and gamma rays, and particle rays such as electron beams.

In the specification, there are cases in which “(meth)acrylic acid” and “(meth)acrylate” are used respectively to indicate either or both of acrylic acid and methacrylic acid and to indicate either or both of acrylate and methacrylate.

In addition, contents will be expressed in terms of mass equivalent unless particularly otherwise described, mass % will indicate the proportion in the total amount of a composition unless particularly otherwise described, and a “solid solution” refers to components in a composition excluding a solvent.

<<<Conductive Member>>>

A conductive member of the invention includes a substrate, conductive layers that are provided on both surfaces of the substrate, and contain a conductive fiber having an average minor axis length of 150 nm or less and a matrix, and intermediate layers that are provided between the substrate and the conductive layers, and contain a compound having a functional group capable of interacting with the conductive fiber, in which, surface resistance values of the two conductive layers are represented by A and B respectively, and A/B is in a range of 1.0 to 1.2. The A and B values are defined as the larger one and the smaller one respectively out of the surface resistance values of both surfaces. In a case in which A and B are equal values, any resistance may be considered as A (A/B becomes one). It is needless to say that A and B satisfy predetermined values suitable for a conductive member.

<<Substrate>>

A variety of substrates can be used as the substrate depending on purposes as long as the substrate is capable of bearing the conductive layer. Generally, a plate-shape or sheet-shaped substrate is used.

The substrate may be transparent or opaque. Examples of a material configuring the substrate include transparent glass such as white-plate glass, blue-plate glass, and silica-coated blue-plate glass; synthetic resins such as polycarbonate, polyether sulfone, polyester, acrylic resins, vinyl chloride resins, aromatic polyamide resins, polyamide-imide, and polyimide; metal such as aluminum, copper, nickel, and stainless steel; other ceramics; silicon wafers used for semiconductor substrates; and the like. On the surfaces of the above-described substrates to be formed the conductive layer, it is possible to carry out as desired a pretreatment such as a corona discharge treatment, a chemical treatment using a silane coupling agent or the like, a plasma treatment, ion plating, sputtering, a gas-phase reaction method, or vacuum deposition.

The thickness of the substrate is set in a desired range depending on use. Generally, the thickness of the substrate is selected from a range of 1 μm to 500 μm, more preferably from a range of 3 μm to 400 μm, and still more preferably from a range of 5 μm to 300 μm.

In a case in which the conductive member is required to be transparent, the total light transmittance of the substrate is 70% or more, more preferably 85% or more, and still more preferably 90% or more.

<<Conductive Layer>>

The conductive layer includes a conductive fiber having an average minor axis length of 150 nm or less and a matrix.

Here, the “matrix” is a collective term for substances forming a layer by including a conductive fiber.

The matrix has a function of stably maintaining the dispersion of the conductive fiber, and may be non-photosensitive or photosensitive.

A photosensitive matrix has an advantage of easily forming a fine pattern through exposure, development, and the like.

<Conductive Fiber Having an Average Minor Axis Length of 150 nm or Less>

The conductive layer according to the invention contains a conductive fiber having an average minor axis length of 150 nm or less.

The conductive fiber may employ any aspect of a solid structure, a porous structure, and a hollow structure, but preferably has any one of a solid structure and a hollow structure. In the invention, there is a case in which a fiber in a solid structure is called a wire, and a fiber in a hollow structure is called a tube respectively.

Examples of a conductive material forming the fiber include metal oxides such as ITO, zinc oxide, and tin oxide, metallic carbon, single metal elements, core shell structures made of a plurality of metal elements, alloys made of a plurality of metal elements, and the like. The conductive material is preferably at least any one of metal and carbon. In addition, the conductive material may be subjected to a surface treatment after being formed into a fibrous shape, and it is also possible to use, for example, a plated metal fiber or the like.

(Metal Nanowires)

Metal nanowires are preferably used as the conductive fiber from the viewpoint of a low surface resistance value and ease of forming a transparent conductive layer. In the invention, the metal nanowires preferably have, for example, an average minor axis length in a range of 1 nm to 150 nm, and an average major axis length in a range of 1 μm to 100 μm.

The average minor axis length (average diameter) of the metal nanowires is preferably 100 nm or less, more preferably 30 nm or less, and still more preferably 20 nm or less. When the average minor axis length is too short, there is a case in which the oxidization resistance and durability of a conductive layer formed using the metal nanowires deteriorate, and therefore the average minor axis length is preferably 5 nm or more. When the average minor axis length exceeds 150 nm, there is a concern that the optical characteristics may be deteriorated due to the degradation of the conductive property, light scattering, and the like, which is not preferable.

The average major axis length of the metal nanowires is preferably in a range of 1 μm to 40 μm, more preferably in a range of 3 μm to 35 μm, and still more preferably in a range of 5 μm to 30 μm. When the average major axis length of the metal nanowires is too long, there is a concern that an aggregate may be generated during the manufacturing of the metal nanowires, and when the average major axis length is too short, there is a case in which it is not possible to obtain a sufficient conductive property.

Here, the average minor axis length (in some cases, called “average diameter”) and average major axis length of the metal nanowires can be obtained by observing a TEM image or an optical microscopic image using, for example, a transmission electron microscope (TEM) or an optical microscope. In the invention, the average minor axis length and average major axis length of the metal nanowires were obtained from the average value after observing 300 metal nanowires using a transmission electron microscope (TEM; manufactured by JEOL Ltd., JEM-2000FX). Meanwhile, in a case in which the cross-sectional surface of the metal nanowire in the minor axis direction is not circular, the length of the longest position in the measurement in the minor axis direction was considered as the minor axis length. In addition, in a case in which the metal nanowires were bent, a circle having the bent metal nanowire as an arc was imaged, and the length of the circular arc computed from the radius and curvature was considered as the major axis length.

In the invention, the proportion of the metal nanowires having the minor axis length (diameter) of 150 nm or less and a major axis length in a range of 5 μm to 500 μm in the entire conductive fiber is preferably 50 mass % or more, more preferably 60 mass % or more, and still more preferably 75 mass % or more in terms of the metal amount.

When the proportion of the metal nanowires having a minor axis length (diameter) of 150 nm or less and a length in a range of 5 μm to 500 μm in the entire conductive fiber is 50 mass % or more, a sufficient conductive property can be obtained, voltage concentration does not easily occur, and the degradation of the durability caused by voltage concentration can be suppressed, which is preferable. When conductive particles having a shape other than a fibrous shape are included in a photosensitive layer, there is a concern that the transparency may degrade in a case in which the plasmon absorption of the conductive particles is strong.

The variation coefficient of the minor axis length (diameter) of the metal nanowires used in the conductive layer according to the invention is preferably 40% or less, more preferably 35% or less, and still more preferably 30% or less.

When the variation coefficient exceeds 40%, there is a case in which the durability deteriorates. The present inventors assume that the above-described fact results from the concentration of the voltage in a wire having a small minor axis length (diameter).

The variation coefficient of the minor axis length (diameter) of the metal nanowires can be obtained by, for example, measuring the minor axis lengths (diameters) of 300 nanowires from a transmission electron microscope (TEM) image, and calculating the standard deviation and average value of the 300 nanowires.

It is possible to employ, for example, an arbitrary shape of a tubular shape, a cubic shape, a columnar shape having a polygonal cross-section, or the like as the shape of the metal nanowire; however, in use requiring high transparency, the tubular shape or a pentagonal or more shape having a cross-section with no sharp corner is preferred.

The cross-sectional shape of the metal nanowire can be detected by applying an aqueous dispersion liquid of the metal nanowires onto the substrate, and observing a cross-section using a transmission electron microscope (TEM).

Any metal may be used as a metal for the metal nanowires with no particular limitation, a combination of two or more metals as well as a single metal may be used, and an alloy can also be used. Among the above-described metals, the metal nanowires are preferably formed of a metal or a metal compound, and the metal nanowires formed of a metal are more preferred.

The metal is preferably at least one metal selected from the group consisting of Periods 4, 5, and 6, more preferably at least one metal selected from Groups 2 to 14, and still more preferably at least one metal selected from Groups 2, 8, 9, 10, 11, 12, 13, and 14 in a large version of the periodic table (IUPAC1991), and the metal is particularly preferably contained as a principal component.

Specific examples of the metal include copper, silver, gold, platinum, palladium, nickel, tin, cobalt, rhodium, iridium, iron, ruthenium, osmium, manganese, molybdenum, tungsten, niobium, tantalum, titanium, bismuth, antimony, lead, alloys thereof, and the like. Among the above-described metals, copper, silver, gold, platinum, palladium, nickel, tin, cobalt, rhodium, iridium, and alloys thereof are preferred, palladium, copper, silver, gold, platinum, tin, and alloys thereof are more preferred, and silver or alloys containing silver are particularly preferred.

(Method for Manufacturing the Metal Nanowires)

The metal nanowires are not particularly limited, and may be produced using any method, but the metal nanowires are preferably manufactured by reducing a metal ion in a solvent obtained by dissolving a halogen compound and a dispersant. In addition, it is preferable to carry out a desalination treatment using an ordinary method after the formation of the mental nanowires from the viewpoint of the dispersibility of the conductive fiber (metal nanowires) in the conductive layer. The method for manufacturing the metal nanowires is described in detail in, for example, JP2012-9219A.

The metal nanowires preferably include an inorganic ion such as an alkali metal ion, an alkali rare earth metal ion, or a halide ion as little as possible. When the metal nanowires are aqueous-dispersed, the electric conductivity is preferably 1 mS/cm or less, more preferably 0.1 mS/cm or less, and still more preferably 0.05 mS/cm or less.

When the metal nanowires are made into aqueous dispersed substances, the viscosity at 20° C. is preferably in a range of 0.5 mPa·s to 100 mPa·s, and more preferably in a range of 1 mPa·s to 50 mPa·s.

Examples of a preferred conductive fiber other than the metal nanowire include a metal nanotube or a carbon nanotube that is a hollow fiber.

(Metal Nanotube)

The material for the metal nanotube is not particularly limited, and may be any metal, and it is possible to use, for example, the above-described materials for the metal nanowires, and the like.

The shape of the metal nanotube may be a single layer or multiple layers, but a single layer is preferred since the conductive property and the thermal conductive property are excellent.

The thickness (the difference between the outer diameter and the inner diameter) of the metal nanotube is preferably in a range of 3 nm to 80 nm, and more preferably in a range of 3 nm to 30 nm.

When the thickness is 3 nm or more, a sufficient oxidization resistance can be obtained, and when the thickness is 80 nm or less, the occurrence of light scattering caused by the metal nanotubes is suppressed.

The average minor axis length of the metal nanotubes is, similar to that of the metal nanowires, required to be 150 nm or less. The preferable average minor axis length is equal to that of the metal nanowires. In addition, the average major axis length is preferably in a range of 1 μm to 40 μm, more preferably in a range of 3 μm to 35 μm, and still more preferably in a range of 5 μm to 25 μm.

The method for manufacturing the metal nanotubes is not particularly limited, and can be appropriately selected depending on purposes, and it is possible to use, for example, the method described in US2005/0056118A.

(Carbon Nanotubes)

The carbon nanotube (CNT) is a substance in which the graphite-like carbon atom surface (graphene sheet) forms a concentric tubular shape in a single layer or multilayers. The carbon nanotube in a single layer is called a single wall nanotube (SWNT), and the carbon nanotube in multilayers is called a multi wall nanotube (MWNT). Particularly, the carbon nanotube in two layers is called a double wall nanotube (DWNT). In the conductive fiber used in the invention, the carbon nanotube may be a single layer or multilayers, but is preferably a single layer since the conductive property and the thermal conductive property are excellent.

(The Aspect Ratio of the Conductive Fiber)

The aspect ratio of the conductive fiber used in the invention is preferably 10 or more. The aspect ratio means the ratio between the long side and short side of a fibrous substance (the ratio of the average major axis length/the average minor axis length).

Meanwhile, in a case in which the conductive fiber has a tubular shape, the outer diameter of the tube is used as the diameter for computing the aspect ratio.

The aspect ratio of the conductive fiber is not particularly limited as long as the aspect ratio is 10 or more, and can be appropriately selected depending on purposes, but is preferably in a range of 50 to 100,000, and more preferably in a range of 100 to 100,000.

When the aspect ratio is less than 10, there is a case in which the conductive fiber does not form a network, and a sufficient conductive property cannot be obtained. When the aspect ratio exceeds 100,000, during the formation of the conductive fiber or in the subsequent handling, the conductive fiber entangles and aggregates before forming a film, and thus there is a case in which a stable coating fluid for forming a conductive layer cannot be obtained.

In a case in which the metal nanowires are used as the conductive fiber, the amount of the metal nanowires included in the conductive layer is preferably in a range of 1 mg/m² to 50 mg/m² since a conductive layer having excellent conductive property and transparency can be easily obtained. The amount of the metal nanowires is preferably set in a range of 3 mg/m².

<Matrix>

As described above, the conductive layer includes the matrix together with the conductive fiber. The inclusion of the matrix stably maintains the dispersion of the conductive fiber in the conductive layer. Furthermore, the inclusion of the matrix in the conductive layer improves the transparency of the conductive layer, and improves thermal resistance, moist heat resistance, and bend flexibility.

The content ratio of the matrix/the conductive fiber is appropriately in a range of 0.001/1 to 100/1 by mass ratio. When the content ratio of the matrix/the conductive fiber is within the above-described range, a conductive layer having an appropriate adhering force to the substrate and an appropriate surface resistance value can be obtained. The content ratio of the matrix/the conductive fiber is more preferably in a range of 0.005/1 to 50/1, and more preferably in a range of 0.01/1 to 20/1 by mass ratio.

As described above, the matrix may be non-photosensitive or photosensitive. Examples of the non-photosensitive matrix include organic polymers and substances configured by including a three-dimensional crosslinking structure having a bond represented by the following general formula (I), and examples of the photosensitive matrix include photoresist compositions.

-M¹-O-M¹- (I)

In the general formula (I), M¹ represents an element selected from the group consisting of Si, Ti, Zr, and Al.

Examples of a preferable non-photosensitive matrix include organic polymers. Specific examples of the organic polymer include polyacryl resins or polymethacryl resins (for example, polyacrylic acid; polymethacrylic acid; for example, methacrylate ester polymers such as poly(methyl methacrylate); polyacrylonitrile; polyvinyl alcohol; polyesters (for example, polyethylene terephthalate (PET), polyester naphthalate, and polycarbonate), novolac resins (for example, phenol formaldehyde resins and cresol formaldehyde resins); polystyrene resins (for example, polystyrene, polyvinyl toluene, polyvinyl xylene, acrylonitrile butadiene styrene copolymers (ABS resins); polyimide; polyamide; polyamide-imide; polyether imide; polysulfide; polysulfone; polyphenylene; polyphenyl ether; polyurethane (PU); epoxy resins; polyolefin (for example, polypropylene, polymethylpentene, polynorbornene, synthetic rubber (for example, EPR, SBR, and EPDM), and cyclic olefins); cellulose; for example, silicon-containing macromolecules such as silicone resins, polysilsesquioxane, and polysilane; polyvinyl chloride (PVC), polyvinyl acetate; fluoro group-containing polymers [for example, polyvinylidene fluoride, polytetrafluoroethylene (TFE) or polyhexafluoropropyelene, fluoro-olefin copolymers, fluorinated hydrocarbon polyolefins (for example, “LUMIFLON” (registered trademark) manufactured by Asahi Glass Co., Ltd.)), amorphous fluorocarbon polymers or copolymers (for example, “CYTOP” (registered trademark) manufactured by Asahi Glass Co., Ltd. and “Teflon” (registered trademark) AF manufactured by DuPont], but are not limited thereto.

The non-photosensitive matrix is preferably a matrix configured by including a three-dimensional crosslinking structure having the bond represented by the following general formula (I) since a conductive layer that is superior in terms of at least one of a conductive property, transparency, the film strength, abrasion resistance, thermal resistance, moist heat resistance, and bend flexibility can be obtained.

-M¹-O-M¹- (I)

In the general formula (I), M¹ represents an element selected from the group consisting of Si, Ti, Zr, and Al.

Examples of the above-described matrix include a sol-gel cured substance.

Preferable examples of the above-described sol-gel cured substance include substances obtained by hydrolyzing, polycondensing, furthermore, heating and drying as desired an alkoxide compound of an element selected from the group consisting of Si, Ti, Zr, and Al (hereinafter, also referred to as “specific alkoxide compound”) (hereinafter, also referred to as “specific sol-gel cured substance”). In a case in which the conductive member according to the invention has a conductive layer including the specific sol-gel cured substance as the matrix, compared with the conductive member having a conductive layer including a matrix other than the specific sol-gel cured substance, a conductive layer that is superior in terms of at least one of a conductive property, transparency, the film strength, abrasion resistance, thermal resistance, moist heat resistance, and bend flexibility can be obtained, which is preferable.

(Specific Alkoxide Compound)

The specific alkoxide compound is preferably at least one compound selected from the group consisting of compounds represented by the following general formula (II) and compounds represented by the following general formula (III) in terms of easy procurement.

M²(OR¹)₄ (II)

In the general formula (II), M² represents an element selected from Si, Ti, and Zr, and each R¹ independently represents a hydrogen atom or a hydrocarbon group.

M³(OR²)aR³₄₋ₐ (III)

In the general formula (III), M³ represents an element selected from Si, Ti, and Zr, each of R² and R³ independently represents a hydrogen atom or a hydrocarbon group, and a represents an integer of 1 to 3.

The hydrocarbon group of R¹ in the general formula (II) or the hydrocarbon group of each of R² and R³ in the general formula (III) is preferably an alkyl group or an aryl group.

In a case in which the hydrocarbon group is an alkyl group, the number of carbon atoms is preferably in a range of 1 to 18, more preferably in a range of 1 to 8, and still more preferably in a range of 1 to 4. In addition, in a case in which the hydrocarbon group is an aryl group, a phenyl group is preferred.

The alkyl group or the aryl group may include a substituent, and examples of an introducible substituent include a halogen atom, an amino group, a mercapto group, and the like. Meanwhile, the compound is a low-molecular compound, and preferably has a molecular weight of 1000 or less.

M² in the general formula (II) and M³ in the general formula (III) are more preferably Si.

Hereinafter, specific examples of the compounds represented by the general formula (II) will be described, but the invention is not limited thereto.

In a case in which M² is Si, that is, the specific alkoxide includes silicon, examples of the compounds include tetramethoxysilane, tetraethoxysilane, tetrapropoxysilane, tetrabutoxysilane, methoxy triethoxysilane, ethoxy trimethoxysilane, methoxy tripropoxysilane, ethoxy tripropoxysilane, propoxy trimethoxysilane, propoxy triethoxysilane, dimethoxy diethoxysilane, and the like. Among the above-described compounds, preferable examples include tetramethoxysilane, tetraethoxysilane, and the like.

In a case in which M² is Ti, that is, the specific alkoxide includes titanium, examples of the compounds include tetramethoxy titanate, tetraethoxy titanate, tetrapropoxy titanate, tetraisopropoxy titanate, tetrabutoxy titanate, and the like.

In a case in which M² is Zr, that is, the specific alkoxide includes zirconium, examples of the compounds include zirconates corresponding to the compounds exemplified as the specific alkoxide containing titanium.

Next, specific examples of the compounds represented by the general formula (III) will be described, but the invention is not limited thereto.

In a case in which M³ is Si and a is 2, that is, the specific alkoxide is a bifunctional alkoxysilane, examples of the compound include dimethyl dimethoxysilane, diethyl dimethoxysilane, propyl methyl dimethoxysilane, dimethyl diethoxysilane, diethyl diethoxysilane, dipropyl diethoxysilane, γ-chloropropyl methyl diethoxysilane, γ-chloropropyl methyl dimethoxysilane, (p-chloromethyl)phenyl methyl dimethoxysilane, γ-bromopropyl methyl dimethoxysilane, acetoxymethyl methyl diethoxysilane, acetoxymethyl methyl dimethoxysilane, acetoxypropyl methyl dimethoxysilane, benzoyloxy propyl methyl dimethoxysilane, 2-(carbomethoxy)ethyl methyl dimethoxysilane, phenyl methyl dimethoxysilane, phenyl ethyl diethoxysilane, phenyl methyl dipropoxysilane, hydroxy methyl methyl diethoxysilane, N-(methyldiethoxysilylpropyl)-O-polyethylene oxide urethane, N-(3-methyl diethoxysilylpropyl)-4-hydroxybutyramide, N-(3-methyldiethoxysilylpropyl)gluconamide, vinyl methyl dimethoxysilane, vinyl methyl diethoxysilane, vinyl methyl dibutoxysilane, isopropenyl methyl dimethoxysilane, isopropenyl methyl diethoxysilane, isopropenyl methyl dibutoxysilane, vinyl methyl bis(2-methoxyethoxy)silane, allyl methyl dimethoxysilane, vinyl decyl methyl dimethoxysilane, vinyl octyl methyl dimethoxysilane, vinyl phenyl methyl dimethoxysilane, isopropenyl phenyl methyl dimethoxysilane, 2-(meth)acryloxy ethyl methyl dimethoxysilane, 2-(meth)acryloxy ethyl methyl diethoxysilane, 3-(meth)acryloxy propyl methyl dimethoxysilane, 3-(meth)acryloxy propyl methyl dimethoxysilane, 3-(meth)-acryloxy propyl methyl bis(2-methoxyethoxy)silane, 3[2-(allyloxycarbonyl)phenylcarbonyloxy]propyl methyl dimethoxysilane, 3-(vinylphenylamino)propyl methyl dimethoxysilane, 3-(vinylphenylamino)propyl methyl diethoxysilane, 3-(vinylbenzylamino)propyl methyl diethoxysilane, 3-[2-(N-vinylphenylmethylamino)ethylamino]propyl methyl dimethoxysilane, 3-[2-(N-isopropenylphenylmethylamino)ethylamino]propyl methyl dimethoxysilane, 2-(vinyloxy)ethyl methyl dimethoxysilane, 3-(vinyloxy)propyl methyl dimethoxysilane, 4-(vinyloxy)butyl methyl diethoxysilane, 2-(isopropenyloxy)ethyl methyl dimethoxysilane, 3-(allyloxy)propyl methyl dimethoxysilane, 10-(allyloxycarbonyl)decyl methyl dimethoxysilane, 3-(isopropenylmethyloxy)propyl methyl dimethoxysilane, 10-(isopropenylmethyloxycarbonyl)decyl methyl dimethoxysilane,

3-[(meth)acryloxypropyl]methyl dimethoxysilane, 3-[(meth)acryloxypropyl]methyl diethoxysilane, 3-[(meth)acryloxymethyl]methyl dimethoxysilane, 3-[(meth)acryloxymethyl]methyl diethoxysilane, γ-glycidoxy propyl methyl dimethoxysilane, N-[3-(meth)acryloxy-2-hydroxypropyl]-3-aminopropyl methyl diethoxysilane, O-[(meth)acryloxyethyl]-N-(methyldiethoxysilylpropyl)urethane, γ-glycidoxy propyl methyl diethoxysilane, β-(3,4-epoxycyclohexyl)ethyl methyl dimethoxysilane, γ-aminopropyl methyl diethoxysilane, γ-aminopropyl methyl dimethoxysilane, 4-aminobutyl methyl diethoxysilane, 11-aminoundecyl methyl diethoxysilane, m-aminophenyl methyl dimethoxysilane, p-aminophenyl methyl dimethoxysilane, 3-aminopropyl methyl-bis(methoxyethoxy)silane, 2-(4-pyridylethyl)methyl diethoxysilane, 2-(methyldimethoxysilylethyl)pyridine, N-(3-methyldimethoxysilylpropyl)pyrrole, 3-(m-aminophenoxy)propyl methyl dimethoxysilane, N-(2-aminoethyl)-3-aminopropyl methyl dimethoxysilane, N-(2-aminoethyl)-3-aminopropyl methyl diethoxysilane, N-(6-aminohexyl)aminomethyl methyl diethoxysilane, N-(6-aminohexyl)aminopropyl methyl dimethoxysilane, N-(2-aminoethyl)-11-aminoundecyl methyl dimethoxysilane, (aminoethylaminomethyl)phenethyl methyl dimethoxysilane, N-3-[(amino(polypropyleneoxy))]aminopropyl methyl dimethoxysilane, n-butyl aminopropyl methyl dimethoxysilane, N-ethyl amino isobutyl methyl dimethoxysilane, N-methyl aminopropyl methyl dimethoxysilane, N-phenyl-γ-aminopropyl methyl dimethoxysilane, N-phenyl-γ-aminomethyl methyl diethoxysilane, (cyclohexylaminomethyl)methyl diethoxysilane, N-cyclohexyl aminopropyl methyl dimethoxysilane, bis(2-hydroxyethyl)-3-aminopropyl methyl diethoxysilane, diethyl aminomethyl methyl diethoxysilane, diethyl aminopropyl methyl dimethoxysilane, dimethyl aminopropyl methyl dimethoxysilane, N-3-methyl dimethoxysilylpropyl-m-phenylenediamine, N,N-bis[3-(methyldimethoxysilyl)propyl]ethylenediamine, bis(methyldiethoxysilylpropyl)amine, bis(methyldimethoxysilylpropyl)amine, bis[(3-methyldimethoxysilyl)propyl]-ethylenediamine,

bis[3-(methyldiethoxysilyl)propyl]urea, bis(methyldimethoxysilylpropyl)urea, N-(3-methyldiethoxysilylpropyl)-4,5-dihydroimidazol, ureidopropyl methyl diethoxysilane, ureidopropyl methyl dimethoxysilane, acetamidopropyl methyl dimethoxysilane, 2-(2-pyridylethyl)thiopropyl methyl dimethoxysilane, 2-(4-pyridylethyl)thiopropyl methyl dimethoxysilane, bis[3-(methyldi ethoxysilyl)propyl]disulfide, 3-(methyldiethoxysilyl)propylsuccinic anhydride, γ-mercaptopropyl methyl dimethoxysilane, γ-mercaptopropyl methyl diethoxysilane, isocyanatopropyl methyl dimethoxysilane, isocyanatopropyl methyl diethoxysilane, isocyanatoethyl methyl diethoxysilane, isocyanatomethyl methyl diethoxysilane, carboxyethyl methylsilane diol sodium salt, N-(methyldimethoxysilylpropyl)ethylenediaminetriacetic acid trisodium salt, 3-(methyldihydroxysilyl)-1-propanesulfonic acid, diethyl phosphate ethyl methyl diethoxysilane, 3-methyl dihydroxy silyl propyl methyl phosphonate sodium salt, bis(methyldiethoxysilyl)ethane, bis(methyldimethoxysilyl)ethane, bis(methyldiethoxysilyl)methane, 1,6-bis(methyldiethoxysilyl)hexane, 1,8-bis(methyldiethoxysilyl)octane, p-bis(methyldimethoxysilylethyl)benzene, p-bis(methyldimethoxysilylmethyl)benzene, 3-methoxy propyl methyl dimethoxysilane, 2-[methoxy(polyethyleneoxy)propyl]methyl dimethoxysilane, methoxy triethyleneoxy propyl methyl dimethoxysilane, tris(3-methyldimethoxysilylpropyl)isocyanurate, [hydroxy(polyethyleneoxy)propyl]methyl diethoxysilane, N,N′-bis(hydroxyethyl)-N,N′-bis(methyldimethoxysilylpropyl)ethylenediamine, bis-[3-(methyldiethoxysilylpropyl)-2-hydroxypropoxy]polyethylene oxide, bis[N,N′-(methyldiethoxysilylpropyl)aminocarbonyl]polyethylene oxide, and bis(methyldiethoxysilylpropyl)polyethylene oxide. Among the above-described compounds, particularly preferable examples include dimethyl dimethoxysilane, diethyl dimethoxysilane, dimethyl diethoxysilane, diethyl diethoxysilane, and the like from the viewpoint of easy procurement and the viewpoint of adhesiveness to a hydrophilic layer.

In a case in which M³ is Si and a is 3, that is, the specific alkoxide is a trifunctional alkoxysilane, examples of the compound include methyl trimethoxysilane, ethyl trimethoxysilane, propyl trimethoxysilane, methyl triethoxysilane, ethyl triethoxysilane, propyl triethoxysilane, γ-chloropropyl triethoxysilane, γ-chloropropyl trimethoxysilane, chloromethyl triethoxysilane, (p-chloromethyl)phenyl trimethoxysilane, γ-bromopropyl trimethoxysilane, acetoxymethyl triethoxysilane, acetoxymethyl trimethoxysilane, acetoxypropyl trimethoxysilane, benzoyloxy propyl trimethoxysilane, 2-(carbomethoxy)ethyl trimethoxysilane, phenyl trimethoxysilane, phenyl triethoxysilane, phenyl tripropoxysilane, hydroxy methyl triethoxysilane, N-(triethoxysilylpropyl)-O-polyethylene oxide urethane, N-(3-triethoxysilylpropyl)-4-hydroxybutylamide, N-(3-triethoxysilylpropyl)gluconamide, vinyl trimethoxysilane, vinyl triethoxysilane, vinyl tributoxysilane, isopropenyl trimethoxysilane, isopropenyl triethoxysilane, isopropenyl tributoxysilane, vinyl tris(2-methoxyethoxy)silane, allyl trimethoxysilane, vinyl decyl trimethoxysilane, vinyl octyl trimethoxysilane, vinyl phenyl trimethoxysilane, isopropenyl phenyl trimethoxysilane, 2-(meth)acryloxy ethyl trimethoxysilane, 2-(meth)acryloxy ethyl triethoxysilane, 3-(meth)acryloxy propyl trimethoxysilane, 3-(meth)acryloxy propyl trimethoxysilane, 3-(meth)-acryloxy propyl tris(2-methoxyethoxy)silane,

3-[2-(allyloxycarbonyl)phenylcarbonyloxy]propyl trimethoxysilane, 3-(vinylphenylamino)propyl trimethoxysilane, 3-(vinylphenylamino)propyl triethoxysilane, 3-(vinylbenzylamino)propyl triethoxysilane, 3-[2-(N-vinylphenylmethylamino)ethylamino]propyl trimethoxysilane, 3-[2-(N-isopropenylphenylmethylamino)ethylamino]propyl trimethoxysilane, 2-(vinyloxy)ethyl trimethoxysilane, 3-(vinyloxy)propyl trimethoxysilane, 4-(vinyloxy)butyl triethoxysilane, 2-(isopropenyloxy)ethyl trimethoxysilane, 3-(allyloxy)propyl trimethoxysilane, 10-(allyloxycarbonyl)decyl trimethoxysilane, 3-(isopropenylmethyloxy)propyl trimethoxysilane, 10-(isopropenylmethyloxycarbonyl)decyl trimethoxysilane, 3-[(meth)acryloxypropyl]trimethoxysilane, 3-[(meth)acryloxypropyl]triethoxysilane, 3-[(meth)acryloxymethyl]trimethoxysilane, 3-[(meth)acryloxymethyl]triethoxysilane, γ-glycidoxy propyl trimethoxysilane, N-[3-(meth)acryloxy-2-hydroxypropyl]-3-aminopropyl triethoxysilane,

O-[(meth)acryloxyethyl]-N-(triethoxysilylpropyl)urethane, γ-glycidoxy propyl triethoxysilane, β-(3,4-epoxycyclohexyl)ethyl trimethoxysilane, γ-aminopropyl triethoxysilane, γ-aminopropyl trimethoxysilane, 4-aminobutyl triethoxysilane, 11-aminoundecyl triethoxysilane, m-aminophenyl trimethoxysilane, p-aminophenyl trimethoxysilane, 3-aminopropyl tris(methoxyethoxyethoxy)silane, 2-(4-pyridylethyl)triethoxysilane, 2-(trimethoxysilylethyl)pyridine, N-(3-trimethoxysilylpropyl)pyrrole, 3-(m-aminophenoxy)propyl trimethoxysilane, N-(2-aminoethyl)-3-aminopropyl trimethoxysilane, N-(2-aminoethyl)-3-aminopropyl triethoxysilane, N-(6-aminohexyl)aminomethyl triethoxysilane, N-(6-aminohexyl)aminopropyl trimethoxysilane, N-(2-aminoethyl)-11-aminoundecyl trimethoxysilane, (aminoethylaminomethyl)phenethyl trimethoxysilane, N-3-[(amino(polypropyleneoxy))]aminopropyl trimethoxysilane, n-butyl aminopropyl trimethoxysilane, N-ethyl amino isobutyl trimethoxysilane, N-methyl aminopropyl trimethoxysilane, N-phenyl-γ-aminopropyl trimethoxysilane, N-phenyl-aminomethyl triethoxysilane, (cyclohexylaminomethyl)triethoxysilane, N-cyclohexyl aminopropyl trimethoxysilane, bis(2-hydroxyethyl)-3-aminopropyl triethoxysilane, diethyl aminomethyl triethoxysilane, diethyl aminopropyl trimethoxysilane, dimethyl aminopropyl trimethoxysilane, N-3-trimethoxysilylpropyl-m-phenylenediamine, N,N-bis[3-(trimethoxysilyl)propyl]ethylenediamine, bis(triethoxysilylpropyl)amine, bis(trimethoxysilylpropyl)amine, bis[(3-trimethoxysilyl)propyl]-ethylenediamine, bis[3-(triethoxysilyl)propyl]urea, bis(trimethoxysilylpropyl)urea, N-(3-triethoxysilylpropyl)-4,5-dihydroimidazol, ureidopropyl triethoxysilane, ureidopropyl trimethoxysilane,

acetamide propyl trimethoxysilane, 2-(2-pyridylethyl)thiopropyl trimethoxysilane, 2-(4-pyridylethyl)thiopropyl trimethoxysilane, bis[3-(triethoxysilyl)propyl]disulfide, 3-(triethoxysilyl)propylsuccinic anhydride, γ-mercaptopropyl trimethoxysilane, γ-mercaptopropyl triethoxysilane, isocyanatopropyl trimethoxysilane, isocyanatopropyl triethoxysilane, isocyanatoethyl triethoxysilane, isocyanatomethyl triethoxysilane, carboxyethylsilane triol sodium salt, N-(trimethoxysilylpropyl)ethylenediaminetriacetic acid trisodium salt, 3-(trihydroxysilyl)-1-propanesulfonic acid, diethyl phosphate ethyl triethoxysilane, 3-trihydroxy silyl propyl methyl phosphonate sodium salt, bis(triethoxysilyl)ethane, bis(trimethoxysilyl)ethane, bis(triethoxysilyl)methane, 1,6-bis(triethoxysilyl)hexane, 1,8-bis(triethoxysilyl)octane, p-bis(trimethoxysilylethyl)benzene, p-bis(trimethoxysilylmethyl)benzene, 3-methoxy propyl trimethoxysilane, 2-[methoxy(polyethyleneoxy)propyl]trimethoxysilane, methoxy triethyleneoxy propyl trimethoxysilane, tris(3-trimethoxysilylpropyl)isocyanurate, [hydroxy(polyethyleneoxy)propyl]triethoxysilane, N,N′-bis(hydroxyethyl)-N,N′-bis(trimethoxysilylpropyl)ethylenediamine, bis-[3-(triethoxysilylpropyl)-2-hydroxypropoxy]polyethylene oxide, bis[N,N′-(triethoxysilylpropyl)aminocarbonyl]polyethylene oxide, and bis(triethoxysilylpropyl)polyethylene oxide. Among the above-described compounds, particularly preferable examples include methyl trimethoxysilane, ethyl trimethoxysilane, methyl triethoxysilane, ethyl triethoxysilane, and the like from the viewpoint of easy procurement and the viewpoint of adhesiveness to a hydrophilic layer.

In a case in which M³ is Ti and a is 2, that is, the specific alkoxide is a bifunctional alkoxy titanate, examples of the compound include dimethyl dimethoxy titanate, diethyl dimethoxy titanate, propyl methyl dimethoxy titanate, dimethyl diethoxy titanate, diethyl diethoxy titanate, dipropyl diethoxy titanate, phenyl ethyl diethoxy titanate, phenyl methyl dipropoxy titanate, dimethyl dipropoxy titanate, and the like.

In a case in which M³ is Ti and a is 3, that is, the specific alkoxide is a trifunctional alkoxy titanate, examples of the compound include methyl trimethoxy titanate, ethyl trimethoxy titanate, propyl trimethoxy titanate, methyl triethoxy titanate, ethyl triethoxy titanate, propyl triethoxy titanate, chloromethyl triethoxy titanate, phenyl trimethoxy titanate, phenyl triethoxy titanate, phenyl tripropoxy titanate, and the like.

In a case in which M³ is Zr, that is, the specific alkoxide contains zirconium, examples of the compounds include zirconates corresponding to the compounds exemplified as the specific alkoxide containing titanium.

In addition, examples of alkoxide compounds of Al that belong to neither the general formulae (II) nor (III) include trimethoxy aluminate, triethoxy aluminate, tripropoxy aluminate, tetraethoxy aluminate, and the like.

The specific alkoxides can be easily procured from commercially available products, and can also be obtained using a well-known synthesis method, for example, a reaction between each metal chloride and an alcohol.

As the specific alkoxide, a single compound may be solely used, or two or more compounds may be used in combination.

Examples of the above-described combination include a combination of (i) at least one selected from the compounds represented by the general formula (II) and (ii) at least one selected from the compounds represented by the general formula (III). For a conductive layer including as the matrix a sol-gel cured substance obtained by combining, hydrolyzing, and polycondensing two specific alkoxide compounds, it is possible to improve the qualities of the conductive layer using the mixing ratio of the specific alkoxide compounds.

Furthermore, M² in the general formula (II) and M³ in the general formula (III) are both more preferably Si.

The content ratio of the compound (ii)/the compound (i) is appropriately in a range of 0.01/1 to 100/1 by mass ratio, and more preferably in a range of 0.05/1 to 50/1.

The conductive layer including the conductive fiber and the specific sol-gel cured substance as the matrix is obtained by applying a coating fluid for forming a conductive layer containing the conductive fiber and the specific sol-gel cured substance on a substrate so as to form a liquid film of the coating fluid, hydrolyzing and polycondensing the specific alkoxide compound in the liquid film so as to produce the specific sol-gel cured substance. The coating fluid for forming a conductive layer is preferably prepared by mixing a dispersion liquid of the conductive fiber (for example, an aqueous solution containing silver nanowires in a dispersed state) and an aqueous solution containing the specific alkoxide compound.

To accelerate the hydrolysis and polycondensation reaction, it is practically preferable to jointly use an acidic catalyst or a basic catalyst since the reaction efficiency is increased. Hereinafter, the catalysts will be described.

[Catalysts]

Any catalyst can be used as the catalysts as long as the catalyst accelerates the hydrolysis and polycondensation reaction of the alkoxide compound.

Examples of the above-described catalyst include acidic and basic compounds, and the compounds are used as they are or are used in the state of being dissolved in a solvent such as water or an alcohol (hereinafter, the acidic compounds and the basic compounds will also be collectively referred to as acid catalysts and basic catalysts, respectively).

There is no particular limitation regarding the concentration of the compound when the acidic or basic compound is dissolved in a solvent, and the concentration may be appropriately selected depending on the characteristics of the acidic or basic compound being used, the desired content of the catalyst, and the like. Here, in a case in which the concentration of the acidic or basic compound configuring the catalyst is high, there is a tendency of the hydrolysis and polycondensation rate becoming fast. However, when a basic catalyst having an excessively high concentration is used, there is a case in which sediment is generated and appears as a defect in the conductive layer. Therefore, in a case in which a basic catalyst is used, the concentration of the compound is desirably 1 N or less in terms of the concentration in an aqueous solution.

There is no particular limitation regarding the type of the acidic catalyst or the basic catalyst; however, in a case in which it is necessary to use a catalyst having a high concentration, a catalyst made up of elements that rarely remain in the conductive layer is preferred. Specific examples of the acidic catalyst include halogenated hydrogen such as hydrochloric acid; carboxylic acids such as nitric acid, sulfuric acid, sulfurous acid, hydrogen sulfide, perchloric acid, hydrogen peroxide, carbonic acid, formic acid, and acetic acid; substituted carboxylic acids obtained by substituting R in the structural formula represented by RCOOH by another element or substituent; sulfonic acid such as benzenesulfonic acid; and the like, and specific examples of the basic catalyst include ammonia water; amines such as ethylamine and aniline; and the like.

A Lewis acid catalyst made of a metal complex can also be preferably used. A particularly preferred catalyst is a metal complex catalyst, which is a metal complex made up of a metal element selected from Groups 2A, 3B, 4A, and 5A in the periodic table and an oxo or hydroxyl oxygen-containing compound selected from β-diketone, ketoester, hydroxycarboxylic acid or esters thereof, amino alcohols, and enolic active hydrogen compounds.

Among the constituent metal elements, Group 2A elements such as Mg, Ca, St, and Ba, Group 3B elements such as Al and Ga, Group 4A elements such as Ti and Zr, and Group 5A elements such as V, Nb and Ta are preferred, and each element forms a complex having an excellent catalytic effect. Among the above-described complexes, complexes obtained from Zr, Al, and Ti are excellent and preferable.

Examples of the oxo or hydroxyl oxygen-containing compound configuring ligands of the metal complex include β-diketones such as acetyl acetone (2,4-pentanedione) and 2,4-phetanedione; ketoesters such as methyl acetoacetate, ethyl acetoacetate, and butyl acetoacetate; hydroxycarboxylic acids and esters thereof such as lactic acid, methyl lactate, salicylic acid, ethyl salicylate, phenyl salicylate, malic acid, tartaric acid, and methyl tartarate; keto alcohols such as 4-hydroxy-4-methyl-2-pentanone, 4-hydroxy-2-pentanone, 4-hydroxy-4-methyl-2-heptanone, and 4-hydroxy-2-heptanone; amino alcohols such as monoethanol amine, N,N-dimethyl ethanol amine, N-methyl-monoethanol amine, diethanol amine, and triethanol amine; enolic active compounds such as methylol melamine, methylol urea, methylol acrylamide, and diethyl ester malonate; and compounds having a substituent instead of the methyl group, methylene group, or carbonyl carbon in acetylacetone (2,4-pentanedione).

A preferable ligand is an acetyl acetone derivative, and the acetyl acetone derivative refers to a compound having a substituent instead of the methyl group, methylene group, or carbonyl carbon in acetylacetone. The substituent substituting the methyl group in acetyl acetone is a straight or branched alkyl group, acyl group, hydroxyalkyl group, carboxyalkyl group, alkoxy group, or alkoxy alkyl group having 1 to 3 carbon atoms, the substituent substituting the methylene group in acetyl acetone is a carboxyl group, or a straight or branched carboxyalkyl group and hydroxyalkyl group having 1 to 3 carbon atoms, and the substituent substituting the carbonyl carbon in acetyl acetone is an alkyl group having 1 to 3 carbon atoms, and in this case, a hydrogen atom is added to carbonyl oxygen, thereby obtaining a hydroxyl group.

Specific examples of the preferable acetyl acetone derivative include ethyl carbonyl acetone, n-propyl carbonyl acetone, i-propyl carbonyl acetone, diacetyl acetone, 1-acetyl-1-propionyl-acetylacetone, hydroxyl ethyl carbonyl acetone, hydroxyl propyl carbonyl acetone, acetoacetate, aceto propionate, diacetoacetate, 3,3-diaceto propionate, 4,4-diacetoacetate, carboxyethyl carbonyl acetone, carboxy propyl carbonyl acetone, and diacetone alcohol. Among the above-described acetyl acetone derivatives, acetyl acetone and diacetyl acetone are particularly preferred. The complex of the above-described acetyl acetone derivative and the above-described metal element is a mononuclear complex in which the metal element is coordinated with one to four acetyl acetone derivatives, and in a case in which the number of possible coordination bonds of the metal element is greater than the total number of possible coordination bonds of the acetyl acetone derivatives, the metal element may be coordinated with ligands that are generally used in an ordinary complex such as a water molecule, a halogen ion, a nitro group, or an ammonio group.

Examples of the preferable metal complex include tris(acetylacetonato)aluminum complex salt, di(acetylacetonato)aluminum.aquo complex salt, mono(acetylacetonato)aluminum.chloro complex salt, di(diacetylacetonato)aluminum complex salt, ethylacetoacetate aluminium diisopropylate, aluminum tris(ethylacetoacetate), cyclic aluminum oxide isopropylate, tris(acetylacetonato)barium complex salt, di(acetylacetonato)titanium complex salt, tris(acetylacetonato)titanium complex salt, di-1-propoxy.bis(acetylacetonato)titanium complex salt, zirconium tris(ethylacetoacetate), zirconium tris(benzoate) complex salt, and the like. The above-described metal complexes are excellent in terms of stability in an aqueous coating fluid and the gelation-accelerating effect in a sol-gel reaction during heating and drying. Among the above-described metal complexes, aluminum ethylacetoacetate diisopropylate, aluminum tris(ethylacetoacetate), di(acetylacetonato)titanium complex salt, and zirconium tris(ethylacetoacetate) are preferred.

While the specification does not describe anything about the pair salt of the above-described metal complex, the type of the pair salt is arbitrary as long as the pair salt is a water-soluble salt that maintains the charge neutrality as the complex compound, and, for example, a form of a salt with which the stoichiometric neutrality is ensured such as nitrate, halogen acid salt, hydrosulfate, or phosphate is used.

Regarding the behaviors of the metal complex in a silica sol-gel reaction, there is a detailed description in J. Sol-Gel. Sci. and Tec. Vol. 16, pp. 209 to 220 (1999). The following scheme is presumed as the reaction mechanism. That is, it is considered that, in the coating fluid, the metal complex has a coordination structure and is stable, and in a dehydration and condensation reaction beginning in a heating and drying step which follows coating, crosslinking is accelerated with a mechanism that is similar to that of the acidic catalyst. In any cases, the use of the metal complex leads to excellence in terms of the stability of the coating fluid over time, the qualities of the coat surface, and favorable durability of the conductive layer.

The above-described metal complex catalyst can be easily procured from commercially available products, and can be obtained using a well-known synthesizing method, for example, a reaction between individual metal chlorides and alcohols.

The catalyst according to the invention is used in the coating fluid for forming a conductive layer at a ratio to nonvolatile components in the coating fluid preferably in a range of 0 mass % to 50 mass %, and more preferably in a range of 5 mass % to 25 mass %. The catalyst may be solely used, or a combination of two or more catalysts may be used.

[Solvent]

The coating fluid for forming a conductive layer may contain an organic solvent as desired to ensure the uniform formability of a coated film.

Examples of the above-described organic solvent include ketone-based solvents such as acetone, methyl ethyl ketone, and diethyl ketone; alcohol-based solvents such as methanol, ethanol, 2-propanol, 1-propanol, 1-butanol, and tert-butanol; chlorine-based solvents such as chloroform and methyl chloride; aromatic solvents such as benzene and toluene; ester-based solvents such as ethyl acetate, butyl acetate, and isopropyl acetate; ether-based solvents such as diethyl ether, tetrahydrofuran, and dioxane; glycol ether-based solvents such as ethylene glycol monomethyl ether, ethylene glycol dimethyl ether; and the like.

In this case, it is effective to add the organic solvent within a range in which no problem occurs in relation to volatile organic compounds (VOC), and the content is preferably 50 mass % or less, and more preferably 30 mass % or less with respect to the total mass of the coating fluid for forming a conductive layer.

In the coated film of the coating fluid for forming a conductive layer, the hydrolysis and condensation reaction of the specific alkoxide compound is caused, and it is preferable to heat and dry the coated film to accelerate the reaction. The heating temperature for accelerating the sol-gel reaction is suitably in a range of 30° C. to 200° C., and more preferably in a range of 50° C. to 180° C. The heating and drying time is preferably in a range of 10 seconds to 300 minutes, and more preferably in a range of 1 minute to 120 minutes.

In the invention, the conductive layers are provided on both surfaces of the substrate, and the detailed manufacturing conditions for forming the conductive layer will be described below in detail.

While it is not evident why a conductive member that has improved in terms of at least one of a conductive property, transparency, abrasion resistance, thermal resistance, moist heat resistance, and bend flexibility resistance can be obtained in a case in which the conductive layer contains the specific sol-gel cured substance as the matrix, but the reason is assumed as described below.

That is, when the conductive layer includes the conductive fiber and the specific sol-gel cured substance obtained by hydrolyzing and polycondensing the specific alkoxide compound as the matrix, a dense conductive layer having a small number of voids is formed even when the proportion of the matrix included in the conductive layer is in a smaller range compared with a conductive layer including an ordinary organic macromolecular resin (for example, an acryl-based resin, a vinyl polymerization-based resin, or the like) as the matrix, and therefore a conductive layer having excellent abrasion resistance, thermal resistance, and moist heat resistance can be obtained. Furthermore, it is assumed that a polymer having a hydrophilic group that serves as a dispersant used during the preparation of the metal nanowires covers at least a part of the metal nanowires, and there are places in which the contact between the metal nanowires is inhibited. However, in a step of forming the sol-gel cured substance, the dispersant covering the metal nanowires is peeled off, and furthermore, is shrunk when the specific alkoxide compound is polycondensed, and therefore the contact points between a number of the metal nanowires increase. Therefore, the contact points between the conductive fiber segments increase, and therefore the conductive property is improved, and high transparency is obtained.

Next, the photosensitive matrix will be described.

The photosensitive matrix may contain a photoresist composition preferable for a lithographic process. A photoresist composition is preferably contained as the matrix since it becomes possible to form a pattern made up of a conductive region and a non-conductive region in the conductive layer using a lithographic process. Among the above-described photoresist compositions, a photopolymerizable composition is particularly preferable since a conductive layer having excellent transparency, flexibility, and adhesiveness to the substrate can be obtained. Hereinafter, the photopolymerizable composition will be described below.

<Photopolymerizable Composition>

The photopolymerizable composition includes (a) an addition-polymerizable unsaturated compound and (b) a photopolymerization initiator generating a radical when irradiated with light as basic components, and further includes (c) a binder and (d) additives other than the above-described components (a) to (c) as desired.

Hereinafter, the above-described components will be described.

[(a) Addition-Polymerizable Unsaturated Compound]

The addition-polymerizable unsaturated compound (hereinafter, also called “polymerizable compound”) of the component (a) is a compound that is polymerized by causing an addition-polymerization reaction in the presence of a radical, and generally, a compound having at least one, more preferably two or more, still more preferably four or more, and further more preferably six or more ethylenic unsaturated double bonds in the molecular end is used.

The addition-polymerizable unsaturated compound has chemical forms of, for example, a monomer, a prepolymer, that is, a dimer, a trimer, an oligomer, a mixture thereof, and the like.

A variety of compounds are known as the above-described polymerizable compound, and the compounds can be used as the component (a).

Among the above-described compounds, trimethylol propane tri(meth)acrylate, pentaerythritol tetra(meth)acrylate, dipentaerythritol hexa(meth)acrylate, dipentaerythritol penta(meth)acrylate are particularly preferred polymerizable compounds from the viewpoint of the film strength.

The content of the component (a) is preferably in a range of 2.6 mass % to 37.5 mass %, and more preferably in a range of 5.0 mass % to 20.0 mass % on the basis of the total mass of the solid content of the above-described coating fluid for forming a conductive layer including a conductive fiber.

[(b) Photopolymerization Initiator]

The photopolymerization initiator of the component (b) is a compound that generates a radical when irradiated with light. Examples of the above-described photopolymerizable initiator include compounds generating an acid radical which ultimately turns into an acid by light irradiation, compounds generating other radicals, and the like. Hereinafter, the former compounds will be called “photo-acid-generating agents”, and the latter compounds will be called “photo-radical-generating agents”.

—Photo-Acid-Generating Agent—

As the photo-acid-generating agent, it is possible to appropriately select and use a substance from photo initiators of photo cationic polymerization, photo initiators of photo radical polymerization, photo decoloring agents of pigments, photo discoloring agents, well-known compounds generating an acid radical by the radiation of an active light ray or a radiant ray which is used for micro resist and the like, and mixtures thereof.

The above-described photo-acid-generating agent is not particularly limited, and can be appropriately selected depending on purposes. Examples thereof include triazine-based compounds having at least one di- or tri-halomethyl group, 1,3,4-oxadiazole, naphthoquinone-1,2-diazide-4-sulfonyl halide, diazonium salts, phosphonium salts, sulfonium salts, iodonium salts, imide sulfonate, oxims sulfonate, diazodisulfone, disulfone, o-nitrobenzyl sulfonate, and the like. Among the above-described photo-acid-generating agents, imide sulfonate, oxims sulfonate, and o-nitrobenzyl sulfonate which are compounds generating sulfonic acid are particularly preferred.

In addition, it is possible to use compounds obtained by introducing a group or a compound that generates an acid radical by the radiation of an active light ray or a radiant ray into the main chain or side chain of a resin, for example, the compounds described in U.S. Pat. No. 3,849,137A, German Patent No. 3914407, JP1988-26653A (JP-S63-26653A), JP1980-164824A (JP-S55-164824A), JP1987-69263A (JP-S62-69263A), JP1988-146038A (JP-S63-146038A), JP1988-163452A (JP-S63-163452A), JP1987-153853A (JP-S62-153851A), and JP1988-146029A (JP-S63-146029A).

Furthermore, it is also possible to use the compounds described in U.S. Pat. No. 3,779,778A, EP126,712B, and the like as the acid-radical-generating agent.

Examples of the triazine-based compound include 2-(4-methoxyphenyl)-4,6-bis(trichloromethyl)-s-triazine, 2-(4-methoxynaphthyl)-4,6-bis(trichloromethyl)-s-triazine, 2-(4-ethoxynaphthyl)-4,6-bis(trichloromethyl)-s-triazine, 2-(4-ethoxycarbonylnaphthyl)-4,6-bis(trichloromethyl)-s-triazine, 2,4,6-tris(monochloromethyl)-s-triazine, 2,4,6-tris(dichloromethyl)-s-triazine, 2,4,6-tris(trichloromethyl)-s-triazine, 2-methyl-4,6-bis(trichloromethyl)-s-triazine, 2-n-propyl-4,6-bis(trichloromethyl)-s-triazine, 2-(α,α,β-trichloroethyl)-4,6-bis(trichloromethyl)-s-triazine, 2-phenyl-4,6-bis(trichloromethyl)-s-triazine, 2-(p-methoxyphenyl)-4,6-bis(trichloromethyl)-s-triazine, 2-(3,4-epoxyphenyl)-4,6-bis(trichloromethyl)-s-triazine, 2-(p-chlorophenyl)-4,6-bis(trichloromethyl)-s-triazine, 2-[1-(p-methoxyphenyl)-2,4-butadienyl]-4,6-bis(trichloromethyl)-s-triazine, 2-styryl-4,6-bis(trichloromethyl)-s-triazine, 2-(p-methoxystyryl)-4,6-bis(trichloromethyl)-s-triazine, 2-(p-i-propyloxystyryl)-4,6-bis(trichloromethyl)-s-triazine, 2-(p-tolyl)-4,6-bis(trichloromethyl)-s-triazine, 2-(4-methoxynaphthyl)-4,6-bis(trichloromethyl)-s-triazine, 2-phenylthio-4,6-bis(trichloromethyl)-s-triazine, 2-benzylthio-4,6-bis(trichloromethyl)-s-triazine, 4-(o-bromo-p-N,N-bis(ethoxycarbonylamino)-phenyl)-2,6-di(trichloromethyl)-s-triazine, 2,4,6-tris(dibromomethyl)-s-triazine, 2,4,6-tris(tribromomethyl)-s-triazine, 2-methyl-4,6-bis(tribromomethyl)-s-triazine, 2-methoxy-4,6-bis(tribromomethyl)-s-triazine, and the like. The above-described triazine-based compounds may be solely used, or two or more triazine-based compounds may be jointly used.

In the invention, among the above-described photo-acid-generating agents (1), compounds generating sulfonic acid are preferred, and oxime sulfonate compounds as described below are particularly preferable from the viewpoint of high sensitivity.

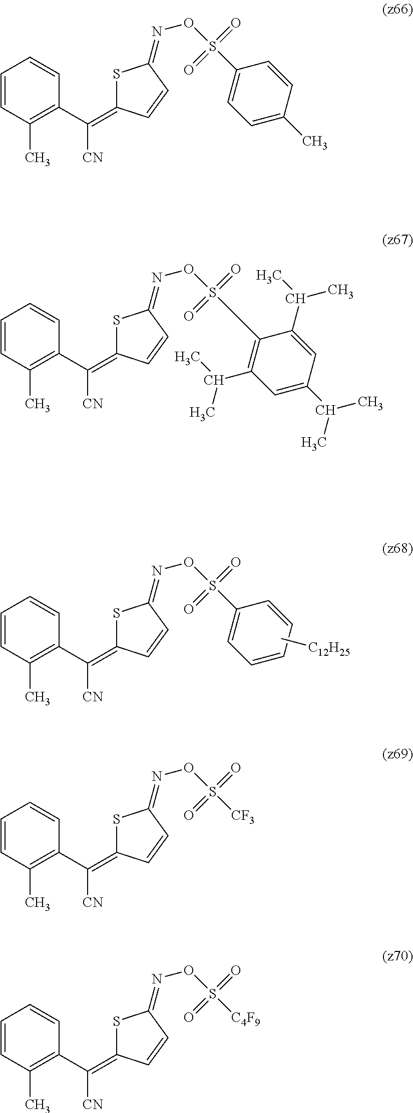

—Photo-Radical-Generating Agent—

The photo-radical-generating agent is a compound that directly absorbs light or is photosensitized so as to cause a decomposition reaction or a hydrogen abstraction reaction, and has a radical-generating function. The photo-radical-generating agent is preferably a compound absorbing light having a wavelength in a range of 300 nm to 500 nm.

A number of compounds are known as the above-described photo-radical-generating agent, and examples thereof include carbonyl compounds, ketal compounds, benzoin compounds, acridine compounds, organic peroxide compounds, azo compounds, coumarin compounds, azide compounds, metallocene compounds, hexaaryl biimidazole compounds, organic boric acid compounds, disulfonic acid compounds, oxims ester compounds, and acyl phosphine (oxide) compounds which are described in JP2008-268884A. The above-described compounds can be appropriately selected depending on purposes. Among the above-described compounds, benzophenone compounds, acetophenone compounds, hexaaryl biimidazole compounds, oxims ester compounds, and acyl phosphine (oxide) compounds are particularly preferred from the viewpoint of the exposure sensitivity.

Examples of the benzophenone compounds include benzophenone, Michler's ketone, 2-methylbenzophenone, 3-methylbenzophenone, N,N-diethylaminobenzophenone, 4-methylbenzophenone, 2-chlorobenzophenone, 4-bromobenzophenone, 2-carboxybenzophenone, and the like. The above-described benzophenone compounds may be solely used, or two or more benzophenone compounds may be jointly used.

Examples of the acetophenone compounds include 2,2-dimethoxy-2-phenylacetophenone, 2,2-di ethoxyacetophenone, 2-(dimethylamino)-2-[(4-methylphenyl)methyl]-1-[4-(4-morpholinyl)phenyl]-1-butanone, 1-hydroxycyclohexylphenylketone, α-hydroxy-2-methylphenylpropanone, 1-hydroxy-1-methylethyl(p-isopropylphenyl)ketone, 1-hydroxy-1-(p-dodecylphenyl)ketone, 2-methyl-1-(4-methylthiophenyl)-2-morpholinopropane-1-one, 1,1,1-trichloromethyl-(p-butylphenyl)ketone, 2-benzyl-2-dimethylamino-1-(4-morpholinophenyl)-butanone-1, and the like. Specific examples of preferable commercially available products include IRGACURE 369, IRGACURE 379, and IRGACURE 907 manufactured by BASF AG, and the like. The above-described acetophenone compounds may be solely used, or two or more acetophenone compounds may be jointly used.

Examples of the hexaarylbiimidazole compounds include a variety of compounds described in JP1994-29285B (JP-H6-29285B), U.S. Pat. No. 3,479,185A, U.S. Pat. No. 4,311,783A, U.S. Pat. No. 4,622,286, and the like. The above-described hexaarylbiimidazole compounds may be solely used, or two or more hexaarylbiimidazole compounds may be jointly used.

Examples of the oxime ester compounds include compounds described in J. C. S. Perkin II (1979) 1653-1660, J. C. S. Perkin II (1979) 156-162, Journal of Photopolymer Science and Technology (1995) 202-232, JP2000-66385A, JP2000-80068A, and JP2004-534797T, and the like. Specific examples of the preferable oxime ester compounds include IRGACURE OXE-01, IRGACURE OXE-02 manufactured by BASF AG; and the like. The above-described oxime ester compounds may be solely used, or two or more oxime ester compounds may be jointly used.

Examples of the acyl phosphine (oxide) compounds include IRGACURE 819, DAROCUR 4265, and DAROCUR TPO manufactured by BASF AG; and the like.

As the photo-radical-generating agent, 2-(dimethylamino)-2-[(4-methylphenyl)methyl]-1-[4-(4-morpholinyl)phenyl]-1-butanone, 2-benzyl-2-dimethylamino-1-(4-morpholinophenyl)-butanone-1, 2-methyl-1-(4-methylthiophenyl)-2-morpholinopropane-1-one, 2,2′-bis(2-chlorophenyl)-4,4′,5,5′-tetraphenylbiimidazole, N,N-diethylaminobenzophenone, and 1-[4-(phenylthio)phenyl]-1,2-octanedione2-(o-benzoyloxime) are particularly preferred from the viewpoint of exposure sensitivity and transparency.

The photopolymerization initiator of the component (b) may be solely used, or two or more photopolymerizable initiators may be jointly used. The content thereof is preferably in a range of 0.1 mass % to 50 mass %, more preferably in a range of 0.5 mass % to 30 mass %, and still more preferably in a range of 1 mass % to 20 mass % on the basis of the total mass of the solid content of the coating fluid for forming a conductive layer including a conductive fiber. In a case in which a pattern including conductive regions and non-conductive regions that will be described below is formed on the conductive layer within the above-described numeric range, favorable sensitivity and pattern formability can be obtained.

[(c) Binder]

A binder can be appropriately selected from alkali-soluble resins that are linear organic high-molecular-weight polymers, and have at least one group accelerating the dissolution property in an alkali (for example, carboxylic group, phosphate group, sulfonic acid group, or the like) in the molecule (preferably, the molecule including an acryl-based copolymer or a styrene-based copolymer as a main chain).

Among the above-described alkali-soluble resins, an alkali-soluble resin that is soluble in an organic solvent and is soluble in an alkali aqueous solution is preferred, and an alkali-soluble resin that has an acid-dissociable group, and becomes alkali-soluble when the acid-dissociable group is dissociated by the action of an acid is particularly preferred. The acid value of the above-described alkali-soluble resin is preferably in a range of 10 mgKOH/g to 250 mgKOH/g, and more preferably in a range of 20 mgKOH/g to 200 mgKOH/g.

Here, the acid-dissociable group refers to a functional group capable of being dissociated in the presence of an acid.

For the manufacturing of the binder, for example, a method in which a well-known radical polymerization method is used can be applied. When the alkali-soluble resin is manufactured using the radical polymerization method, a variety of polymerization conditions such as temperature, pressure, the type and amount of a radical initiator, and the type of a solvent can be easily set by a person skilled in the art, and it is possible to specify the conditions experimentally.

The linear organic high-molecular-weight polymer is preferably a polymer having carboxylic acid in a side chain.

Examples of the polymer having carboxylic acid in a side chain include methacrylic acid copolymers, acrylic acid copolymers, itaconic acid copolymers, crotonic acid copolymers, maleic acid copolymers, partially-esterified maleic acid copolymers which are described in JP1984-44615A (JP-S59-44615A), JP1979-34327B (JP-S54-34327B), JP1983-12577B (JP-S58-12577B), JP1979-25957B (JP-S54-25957B), JP1984-53836A (JP-S59-53836A), and JP1984-71048A (JP-S59-71048A), acidic cellulose derivatives having carboxylic acid in a side chain, polymers obtained by adding an acid anhydride to a polymer having a hydroxyl group, and the like, and furthermore, high-molecular-weight polymers having a (meth)acryloyl group in a side chain also can be preferable examples.

Among the above-described polymers, benzyl (meth)acrylate/(meth)acrylic acid copolymers and multicomponent copolymers made up of benzyl (meth)acrylate/(meth)acrylic acid/other monomer are particularly preferred.

Furthermore, high-molecular-weight polymers having a (meth)acryloyl group in a side chain and multicomponent copolymers made up of (meth)acrylic acid/glycidyl (meth)acrylate/other monomer also can be useful examples. The above-described polymers can be mixed in an arbitrary amount.

In addition to the above-described polymers, examples thereof include 2-hydroxypropyl (meth)acrylate/polystyrene macromonomer/benzyl methacrylate/methacrylic acid copolymers, 2-hydroxy-3-phenoxypropyl acrylate/polymethyl methacrylate macromonomer/benzyl methacrylate/methacrylic copolymers, 2-hydroxyethyl methacrylate/polystyrene macromonomer/methyl methacrylate/methacrylic acid copolymers, 2-hydroxyethyl methacrylate/polystyrene macromonomer/benzyl methacrylate/methacrylic acid copolymers, and the like which are described in JP1995-140654A (JP-H7-140654A).

The specific constituent unit in the alkali-soluble resin is preferably (meth)acrylic acid and other monomers capable of copolymerizing with the (meth)acrylic acid.

Examples of the other monomers capable of copolymerizing with the (meth)acrylic acid include alkyl (meth)acrylate, aryl (meth)acrylate, vinyl compounds, and the like. In the above-described monomers, the hydrogen atom in the alkyl group or the aryl group may be substituted by a substituent.

Examples of the alkyl (meth)acrylate or the aryl (meth)acrylate include methyl (meth)acrylate, ethyl (meth)acryl ate, propyl (meth)acrylate, butyl (meth)acrylate, isobutyl (meth)acrylate, pentyl (meth)acrylate, hexyl (meth)acrylate, octyl (meth)acrylate, phenyl (meth)acrylate, benzyl (meth)acrylate, tolyl (meth)acrylate, naphthyl (meth)acrylate, cyclohexyl (meth)acrylate, dicyclopentanyl (meth)acrylate, dicyclopentenyl (meth)acrylate, dicyclopentenyloxy ethyl (meth)acrylate, glycidyl methacrylate, tetrahydrofurfuryl methacrylate, polymethyl methacrylate macromonomers, and the like. The above-described alkyl (meth)acrylates may be solely used, or two or more alkyl (meth)acrylates may be jointly used.

Examples of the vinyl compounds include styrene, α-methylstyrene, vinyltoluene, acrylonitrile, vinyl acetate, N-vinylpyrrolidone, polystyrene macromonomer, CH₂═CR¹R² [wherein R¹ represents a hydrogen atom or an alkyl group having 1 to 5 carbon atoms; and R² represents an aromatic hydrocarbon ring having 6 to 10 carbon atoms], and the like. The above-described vinyl compounds may be solely used or two or more vinyl compounds may be jointly used.

The weight-average molecular weight of the binder is preferably in a range of 1,000 to 500,000, more preferably in a range of 3,000 to 300,000, and still more preferably in a range of 5,000 to 200,000 in terms of the alkali dissolution rate, film properties, and the like. Furthermore, the ratio of the weight-average molecular weight/the number-average molecular weight (Mw/Mn) is preferably in a range of 1.00 to 3.00, and more preferably in a range of 1.05 to 2.00.

Here, the weight-average molecular weight can be obtained through measurement using gel permeation chromatography and the use of the standard polystyrene calibration curve.

The content of the binder of the component (c) is preferably in a range of 5 mass % to 90 mass %, more preferably in a range of 10 mass % to 85 mass %, and still more preferably in a range of 20 mass % to 80 mass % on the basis of the total mass of the solid content of the photopolymerizable composition including the above-described conductive fiber. When the content is within the above-described preferable range, it is possible to satisfy both developing properties and the conductive properties of the conductive fiber.

[(d) Additives Other than the Above-Described Components (a) to (c)]

Examples of additives other than the above-described components (a) to (c) include a variety of additives such as a chain transfer agent, a crosslinking agent, a dispersant, a solvent, a surfactant, an antioxidant, a sulfurization inhibitor, a metal corrosion inhibitor, a viscosity adjuster, and an antiseptic agent.

(d-1) Chain Transfer Agent

The chain transfer agent is used to improve the exposure sensitivity of the photopolymerizable composition. Examples of the chain transfer agent include N,N-dialkyl amino alkyl benzate ester such as N,N-dimethyl amino ethyl benzoate ester; mercapto compounds having a heterocyclic ring such as 2-mercaptobenzothiazole, 2-mercaptobenzooxazole, 2-mercaptobenzoimidazole, N-phenylmercaptobenzoimidazole, and 1,3,5-tris(3-mercaptobutyloxyethyl)-1,3,5-triazine-2,4,6(1H,3H,5H)-trione; aliphatic polyfunctional mercapto compounds such as pentaerythritol tetraquis(3-mercaptopropionate), pentaerythritol tetrakis(3-mercaptobutylate), and 1,4-bis(3-mercaptobutylyloxy)butane; and the like. The above-described chain transfer agents may be solely used, or two or more chain transfer agents may be jointly used.

The content of the chain transfer agent is preferably in a range of 0.01 mass % to 15 mass %, more preferably in a range of 0.1 mass % to 10 mass %, and still more preferably in a range of 0.5 mass % to 5 mass % on the basis of the total mass of the solid content of the photopolymerizable composition including the conductive fiber.

(d-2) Crosslinking Agent

The crosslinking agent is a compound that forms a chemical bond using a free radical or an acid and heat, and cures the conductive layer, and examples thereof include melamine-based compounds substituted by at least one group selected from a methylol group, an alkoxy methyl group, and an acyloxy methyl group, guanamine-based compounds, glycoluril-based compounds, urea-based compounds, phenol-based compounds or ether compounds of phenol, epoxy-based compounds, oxetane-based compounds, thioepoxy-based compounds, isocyanate-based compounds, azide-based compounds, compounds having an ethylenic unsaturated group such as a methacryloyl group or an acryloyl group, and the like. Among the above-described crosslinking agents, epoxy-based compounds, oxetane-based compounds, and compounds having an ethylenic unsaturated group are particularly preferred in terms of film properties, thermal resistance, and solvent resistance.

In addition, the oxetane resin can be solely used, or can be mixed with an epoxy resin for use. Particularly, it is preferable to jointly use the oxetane resin with an epoxy resin since the reactivity is high, and the film properties are improved.

Meanwhile, in a case in which a compound having an ethylenic unsaturated double bond group is used as the crosslinking agent, the crosslinking agent is also contained in the (c) polymerizable compound, and it is necessary to consider that the content of the crosslinking agent is within the content of the (c) polymerizable compound in the invention.

The content of the crosslinking agent is preferably in a range of 1 part by mass to 250 parts by mass, and more preferably in a range of 3 parts by mass to 200 parts by mass when the total mass of the solid content of the photopolymerizable composition including the conductive fiber is set to 100 parts by mass.

(d-3) Dispersant

The dispersant is used to prevent the aggregation of the conductive fiber and disperse the conductive fiber in the photopolymerizable composition. The dispersant is not particularly limited as long as the dispersant is capable of dispersing the conductive fiber, and can be appropriately selected depending on purposes.

In a case in which the metal nanowires are used as the conductive fiber, it is possible to use, for example, a dispersant that is commercially available as a pigment dispersant, and particularly, a polymer dispersant having a property of being adsorbed to the metal nanowires is preferred. Examples of the polymer dispersant include polyvinyl pyrrolidone, BYK series (manufactured by BYK Japan KK), SOLSPERSE series (manufactured by The Lubrizol Corporation), AJISPERSE series (manufactured by Ajinomoto Co., Inc.), and the like.

Meanwhile, in a case in which the polymer dispersant is further added separately as the dispersant in addition to the dispersant used for the manufacturing of the metal nanowires, the polymer dispersant is also contained in the binder of the component (c), and it is necessary to consider that the content of the polymer dispersant is within the content of the component (c).

The content of the dispersant is preferably in a range of 0.1 parts by mass to 50 parts by mass, more preferably in a range of 0.5 parts by mass to 40 parts by mass, and particularly preferably in a range of 1 part by mass to 30 parts by mass with respect to 100 parts by mass of the binder of the component (c).

It is preferable to set the content of the dispersant to 0.1 parts by mass or more since the aggregation of the metal nanowires in the dispersion liquid is effectively suppressed, and to set the content to 50 parts by mass or less since a stable liquid film is formed in a coating step, and the occurrence of an uneven coat is suppressed.

(d-4) Solvent

The solvent is a component used to turn a photopolymerizable composition containing the metal nanowires into a coating fluid for forming a film on the base material surface, and can be appropriately selected depending on purposes. Examples of the solvent include propylene glycol monomethyl ether, propylene glycol monomethyl ether acetate, ethyl 3-ethoxypropionate, methyl 3-methoxypropionate, ethyl lactate, 3-methoxybutanol, water, 1-methoxy-2-propanol, isopropyl acetate, methyl lactate, N-methylpyrrolidone (NMP), γ-butyrolactone (GBL), propylene carbonate, and the like. The above-described solvents may be solely used, or two or more solvents may be jointly used.

The solid content concentration of the coating fluid containing the above-described solvent is preferably in a range of 0.1 mass % to 20 mass %.

(d-5) Metal Corrosion Inhibitor

The photopolymerizable composition preferably contains a metal corrosion inhibitor of the metal nanowires. The metal corrosion inhibitor is not particularly limited, and can be appropriately selected depending on purposes. Preferable examples thereof include thiols, azoles, and the like.

When the metal corrosion inhibitor is contained, it is possible to exhibit a superior anti-rust effect. The metal corrosion inhibitor can be added to a photopolymerizable composition including the metal nanowires in a state of being dissolved in a suitable solvent or in a powder form, or can be supplied by producing a conductive layer, and then immersing the conductive layer in a metal corrosion inhibitor bath.

In a case in which the metal corrosion inhibitor is added, the content thereof is preferably set in a range of 0.5 mass % to 10 mass % with respect to the metal nanowires.

Additionally, regarding the matrix, the polymer compound serving as the dispersant used for the manufacturing of the metal nanowires can be used as at least a part of components that configure the matrix.

In the conductive layer according to the invention, in addition to the conductive fiber, other conductive materials such as conductive fine particles can be jointly used as long as the effect of the invention is not impaired. For example, in a case in which the metal nanowires are used as the conductive fiber, the content ratio of the metal nanowires having an aspect ratio of 10 or more to a composition for forming a photosensitive layer is preferably 50% or more, more preferably 60% or more, and particularly preferably 75% or more in terms of volume ratio from the viewpoint of the effect. Hereinafter, the proportion of the metal nanowires will be referred to as “the ratio of the metal nanowires” in some cases.

When the ratio of the metal nanowires is set to 50%, a dense network of the metal nanowires is formed, and it is possible to easily obtain a conductive layer having a high conductive property. In addition, particles having shapes other than those of the metal nanowires are not preferable since the particles do not significantly contribute to the conductive property, and are thus absorbed. Particularly, in the case of metal having a spherical shape or the like, there is a case in which the transparency deteriorates when the plasmon absorption is strong.

Here, the ratio of the metal nanowires can be determined, for example, in a case in which the metal nanowires are silver nanowires, by separating the silver nanowires and other particles by filtrating an aqueous dispersion of the silver nanowires, and measuring the amount of silver remaining on the filter paper and the amount of silver that has passed through the filter paper respectively using an ICP emission spectrometry apparatus. The aspect ratio of the metal nanowires is detected by observing the metal nanowires remaining on the filter paper using a TEM, observing the minor axis lengths of 300 metal nanowires, and investigating the distribution thereof.

The method for measuring the average minor axis length and average major axis length of the metal nanowires is as described above.

There is no particular limitation regarding the method for applying the coating fluid for forming a conductive layer on the substrate, and the coating fluid for forming a conductive layer can be applied using an ordinary coating method. The method for applying the coating fluid for forming a conductive layer can be appropriately selected depending on purposes, and examples thereof include a roll coating method, a bar coating method, a dip coating method, a spin coating method, a casting method, a die coating method, a blade coating method, a gravure coating method, a curtain coating method, a spray coating method, a doctor coating method, and the like.

<<Intermediate Layer>>

An intermediate layer containing a compound having a functional group capable of interacting with the conductive fiber included in the conductive layer is provided between the substrate and the conductive layer.

Here, the above-described “functional group capable of interacting with the conductive fiber” refers to a group generating an ionic bond, a covalent bond, a van der Waals bond, or a hydrogen bond with the conductive fiber. When the above-described intermediate layer is provided, it becomes possible to improve at least one of the adhesiveness between the substrate and the conductive layer, the total light transmittance of the conductive layer, the haze of the conductive layer, and the film strength of the conductive layer.

Furthermore, it becomes easy to manufacture a conductive member in which the ratio (A/B) of the surface resistance value A of the conductive layer provided on a first surface of the substrate to the surface resistance value B of the conductive layer provided on a second surface of the substrate is in a range of 1.0 to 1.2.

<The Compound Having a Functional Group Capable of Interacting with the Conductive Fiber>

The compound having a functional group capable of interacting with the conductive fiber included in the intermediate layer is selected depending on the type of the conductive fiber used in the conductive layer.

For example, in a case in which the conductive fiber is silver nanowires, the functional group capable of interaction is more preferably at least one selected from the group consisting of an amide group, an amino group, a mercapto group, a carboxylic acid group, a sulfonic acid group, a phosphate group, a phosphonate group, salts thereof, and an epoxy group, still more preferably at least one selected from the group consisting of an amino group, a mercapto group, a phosphate group, a phosphonate group, salts thereof, and an epoxy group, and most preferably an amino group or an epoxy group.

Examples of compounds having the above-described functional group include compounds having an amide group such as ureidopropyl triethoxysilane, polyacrylamide, and polymethacrylamide; compounds having an amino group such as N-(2-aminoethyl)-3-aminopropyl trimethoxysilane, 3-aminopropyl triethoxysilane, bis(hexamethylene)triamine, N,N′-bis(3-aminopropyl)-1,4-butadiamines tetrahydrochloride, spermine, diethylene triamine, m-xylene diamine, and methaphenylene diamine; compounds having a mercapto group such as 3-mercapto propyl trimehoxysilane, 2-mercaptobenzothiazole, and toluene-3,4-dithiol; compound having a sulfonic acid or a group of a salt thereof such as poly(p-sodium styrenesulfonate) and poly(2-acrylamide-2-methylpropane sulfonate); compounds having a carboxylic acid group such as polyacrylic acid, polymethacrylic acid, polyasparaginic acid, teraphthalic acid, cinnamic acid, fumaric acid, and succinic acid; compounds having a phosphate group such as PHOSMER PE, PHOSMER CL, PHOSMER M, PHOSMER MH, polymers thereof, POLYPHOSMER M-101, POLYPHOSMER PE-201, and POLYPHOSMER MH-301; and compounds having a phosphonate group such as phenyl phosphonate, decyl phosphonate, methylene diphosphoate, vinyl phosphonate, and allyl phosphoate.

In a case in which silver nanowires are used as the conductive fiber included in the conductive layer, a particularly preferable intermediate layer is a sol-gel film obtained by hydrolyzing and polycondensing an alkoxide compound of Si having a functional group capable of interacting with the silver nanowires (for example, an amino group, an epoxy group, or the like). Examples of the alkoxy compound that can be used to form the sol-gel film include 3-glycidoxypropyltrimethoxysilane, 2-(3,4-epoxycyclohexyl)ethyltrimethoxysilane, 3-glycidoxypropylmthyldimethoxysilane, 3-glycidoxypropylmethyldiethoxysilane, 3-glycidoxypropyltriethoxysilane, N-(2-aminoethyl)-3-aminopropylmethyldimethoxysilane, N-(2-aminoethyl)-3-aminopropyltrimethoxysilane, 3-aminopropyltrimethoxysilane, 3-aminopropyltriethoxysilane, 3-triethoxysilyl-N-(1,3-dimethyl butylidene)propylamine, N-phenyl-3-aminopropyltrimethoxysilane, N-(vinylbenzyl)-2-aminoethyl-3-aminopropyltrimethoxysilane, and the like.

The thickness of the intermediate layer is preferably set in a range of 0.01 nm to 1000 nm since a conductive member having conductive layers and a substrate strongly attached to each other is obtained, and thus it becomes easy to adjust the ratio (A/B) of the surface resistance value between two conductive layers formed on the front and back surfaces of the substrate in a range of 1.0 to 1.2. The thickness of the intermediate layer is more preferably in a range of 0.1 nm to 100 nm, and most preferably in a range of 0.1 nm to 10 nm.

A plurality of adhesive layers may be provided as desired between the substrate and the intermediate layer. When the above-described adhesive layers are provided, a conductive member having the intermediate layer and the substrate more strongly attached to each other can be obtained.

Examples of a material for forming the adhesive layers include a polymer used as an adhesive, a silane coupling agent, a titanium coupling agent, a sol-gel film obtained by hydrolyzing and polycondensing an alkoxide compound of Si, and the like.

The thickness of the adhesive layer is preferably in a range of 0.01 μm to 100 μm, more preferably in a range of 0.1 μm to 10 μm, and most preferably in a range of 0.1 μm to 5 μm.

<<<Method for Manufacturing the Conductive Member>>>

A method for manufacturing a conductive member according to the invention is as described below.

First, a case in which the matrix included in the conductive layer is a substance configured by including a three-dimensional crosslinking structure having the bond represented by the following general formula (I) will be described.

A method for manufacturing a conductive member, including:
a step of forming a first intermediate layer on a first surface of a substrate by applying a coating fluid for forming an intermediate layer containing a compound having a functional group capable of interacting with a conductive fiber to form a coated film, and drying the coated film;
a step of forming a first conductive layer on the first intermediate layer by applying a coating fluid for forming a conductive layer containing a conductive fiber having an average minor axis length of 150 nm or less and at least one alkoxide compound of an element selected from the group consisting of Si, Ti, Zr, and Al to form a coated film, hydrolyzing and polycondensing the alkoxide compound in the coated film through heating so as to form a three-dimensional crosslinking structure having the bond represented by the following general formula (I) in the coated film,
a step of forming a second intermediate layer on a second surface of the substrate forming a coated film by applying a coating fluid for forming an intermediate layer containing a compound having a functional group capable of interacting with a conductive fiber to form a coated film, and drying the coated film; and
a step of forming a second conductive layer on the second intermediate layer by applying a coating fluid for forming a conductive layer containing a conductive fiber having an average minor axis length of 150 nm or less and at least one alkoxide compound of an element selected from the group consisting of Si, Ti, Zr, and Al to form a coated film, hydrolyzing and polycondensing the alkoxide compound in the coated film through heating so as to form a three-dimensional crosslinking structure having the bond represented by the following general formula (I) in the coated film,

-M¹-O-M¹- (I)
in the general formula (I), M¹ represents an element selected from the group consisting of Si, Ti, Zr, and Al.

In the method for manufacturing a conductive member according to the invention, it is preferable to carry out a surface treatment on either or both of the first surface and second surface of the substrate and, in a case in which the adhesive layers are provided, on either or both of the surfaces of the adhesive layers since a conductive member having strong adhering forces between the respective layers can be obtained.

Examples of the surface treatment include a corona discharging treatment, a plasma treatment, a glow discharging treatment, an ultraviolet-ozone treatment, and the like. The above-described surface treatments may be solely carried out, or two or more surface treatments may be carried out in combination.

Among the above-described surface treatments, the corona discharging treatment is preferred since the corona discharging treatment can be carried out using a relatively simple apparatus, and the effect is excellent. The corona surface treatment is preferably carried out at an irradiation energy in a range of 0.1 J/m² to 10 J/m², and more preferably in a range of 0.5 J/m² to 5 J/m².

In the method for manufacturing a conductive member according to a first preferred embodiment of the invention, both the first surface (A surface) and the second surface (B surface) of the substrate are surface-treated before the step of forming the first intermediate layer. Then, it becomes easy to manufacture a conductive member having the above-described A/B in a range of 1.0 to 1.2.

Generally, it is common to carry out the surface treatment on the first surface (A surface) of the substrate, form the first intermediate layer, then, carry out the surface treatment on the second surface (B surface) of the substrate, and form the second intermediate layer sequentially from the viewpoint of productivity; however, when the intermediate layers are formed in the above-described sequence, the surface shape of the intermediate layer on the A surface deteriorates, consequently, the surface resistance value of the A surface after the formation of the conductive layer increases, and it becomes difficult to form a conductive member having the above-described A/B in a range of 1.0 to 1.2. The reason is not evident, but is considered as described below.

That is, it is considered that, when the surface treatment is carried out on the first surface (A surface) of the substrate, the first intermediate layer is formed, and then the surface treatment is carried out on the second surface (B surface) of the substrate, unintentionally, a weak corona treatment effect is also developed on the first surface (A surface) of the substrate, and the intermediate layer formed on the first surface (A surface) of the substrate is deteriorated.

The corona treatment is originally intended to obtain a treatment effect only on a single surface of a film that has been subjected to the treatment, but it is considered that the above-described problem results from the fact that a small amount of air is infused between the back surface (non-treated surface) of the film and the treatment roll, and an ionizing phenomenon occurs when a voltage is applied to the air.

In the method for manufacturing a conductive member according to the invention, for example, the drying is carried out at a temperature of 40° C. or lower with an air flow in a range of 0.2 m/s to 1 m/s (more preferably in a range of 0.2 m/s to 0.5 m/s) during a period from the initial stage of the drying to constant-rate drying (the dry measure reaches 800% from 400% at DRY (in terms of the dry measure)) to prevent the unnecessary coated film disarray caused by air and a high temperature, and then, from decreasing drying and thereafter (the dry measure is 400% or less at DRY (in terms of the dry measure)), the drying is carried out at a high temperature in a range of 40° C. to 140° C. under dried air to progress a film-curing reaction. To more efficiently supply heat, an arbitrary value is preferably employed as the air speed on the film surface in a range of 0.2 m/s to 5 m/s. Furthermore, to progress the film-curing reaction, the coated film temperature under a high temperature becomes important, and it is desirable to maintain the coated film temperature in a range of 60° C. to 140° C. for 30 seconds or longer.

The coated film temperature mentioned herein refers to a coated film temperature at which the coated film temperature becomes substantially constant in a period of the decreasing drying and thereafter, and was obtained from the average value after continuously measuring the central section of a sample using a digital infrared temperature sensor FT-H20 manufactured by Keyence Corporation for five seconds at a detection distance of 60 mm between the sensor and the coated film. The coated film temperature was realized by adjusting the temperature of the dried air.

Regarding the drying conditions when the intermediate layers are provided, in consideration of the transportation property, it is desirable to maintain the film surface temperature in a decreasing drying range at a temperature that is 60° C. or more higher than a temperature at which the film hardness can be ensured for 30 seconds or longer.

Furthermore, in a case in which the performances are affected on the surface after the first round of the drying, in the second round of the drying, it is also possible to introduce air having a lower temperature than that of the front surface into a back surface side (the surface side in the first round) as necessary or to selectively suppress the temperature increase in the back surface by cooling a back support roll.

In the method for manufacturing a conductive member according to a second preferred embodiment of the invention, both the first surface and second surface of the substrate are surface-treated before the step of forming the first intermediate layer, and at least one of the condition that the temperature of the coated film when the coated film is dried in the step of forming the first intermediate layer (B surface) is lower than a temperature of the coated film when the coated film is dried in the step of forming the second intermediate layer (A surface) by 20° C. or more and the condition that the temperature of the coated film during the heating in the step of forming the first conductive layer (B surface) is lower than a temperature of the coated film during the heating of the coated film in the step of forming the second conductive layer (A surface) by 20° C. or more is satisfied.

Then, it becomes easy to manufacture a conductive member having the above-described A/B in a range of 1.0 to 1.2. The reason therefor is not evident, but is considered as described below. That is, while the intermediate layer is formed even before the second surface (B surface) of the substrate is dried after the surface treatment, the first surface (A surface) of the substrate is exposed to the first intermediate layer drying-temperature during a period from the end of the surface treatment to the formation of the second intermediate layer, and therefore the surface treatment effects become weak.

Furthermore, there is another difference between the first intermediate layer (B surface) formed on the second surface of the substrate and the second intermediate layer (A surface) formed on the first surface of the substrate in that, to the temperature when the coated film of the coating fluid for forming an intermediate layer is dried (hereinafter, also referred to as “intermediate layer-drying temperature”), the early-formed first intermediate layer (B surface) is exposed twice, but the later-formed second intermediate layer (A surface) is exposed only once.

As described above, the differences in the number of exposure to the intermediate layer-drying temperature between the first surface of the substrate and the second surface of the substrate, and between the first intermediate layer and the second intermediate layer appear in a form of the difference between the surface resistance value A of the second conductive layer and the surface resistance value B of the first conductive layer in the conductive member.

The same event also occurs between the step of forming the first conductive layer (B surface) formed on the first intermediate layer and the step of forming the second conductive layer (A surface) formed on the second intermediate layer. That is, to the coated film temperature during the heating of the coated film of the coating fluid for forming a conductive layer (hereinafter, also referred to as “conductive layer-forming temperature”), the early-formed first conductive layer is exposed twice, but the later-formed second conductive layer is exposed only once. As described above, the differences in the number of exposure to the conductive layer-forming temperature between the first conductive layer and the second conductive layer appear in a form of the difference between the surface resistance value of the second conductive layer and the surface resistance value of the first conductive layer in the conductive member together with the difference in the number of exposure to the intermediate layer-drying temperature between the surface-treated substrate and the surface-treated intermediate layer.

In the method for manufacturing a conductive member according to the second preferred embodiment of the invention, at least one of the condition that the temperature of the coated film when the coated film is dried in the step of forming the first intermediate layer is a temperature lower than the temperature of the coated film when the coated film is dried in the step of forming the second intermediate layer by 20° C. or more and the condition that the temperature of the coated film during the heating in the step of forming the first conductive layer is a temperature lower than the temperature of the coated film during the heating of the coated film in the step of forming the second conductive layer by 20° C. or more is satisfied.

As described above, when either or both of the condition that the intermediate layer-drying temperature of the early-formed intermediate layer is set to a temperature lower than the intermediate layer-drying temperature of the later-formed intermediate layer by 20° C. or more and the condition that the conductive layer-forming temperature of the early-formed conductive layer is set to a temperature lower than the conductive layer-forming temperature of the later-formed conductive layer by 20° C. or more are satisfied, the difference between the resistance values of both surfaces becomes small.

It is preferable to satisfy at least one of the condition that the temperature of the coated film when the coated film is dried in the step of forming the early-formed first intermediate layer is a temperature lower than the temperature of the coated film when the coated film is dried in the step of forming the later-formed second intermediate layer by 40° C. or more and the condition that the temperature of the coated film during the heating in the step of forming the early-formed first conductive layer is a temperature lower than the temperature of the coated film during the heating of the coated film in the step of forming the later-formed second conductive layer by 40° C. or more since A/B becomes closer to 1.0, and furthermore, the film strength also improves.

In the method for manufacturing a conductive member according to a third preferred embodiment of the invention, both the first surface and second surface of the substrate are surface-treated before the step of forming the first intermediate layer, and the solid content application amount of the coating fluid for forming an intermediate layer in the step of forming the second intermediate layer is set in a range of two to three times of the solid content application amount of the coating fluid for forming an intermediate layer in the step of forming the first intermediate layer. Here, the above-described “solid content application amount” refers to the amount of components included in the coating fluid for forming an intermediate layer other than the solvent.

The above-described method also offsets the difference between the A value and the B value. The reason therefor is not evident, but is considered as described below.

That is, it is considered that, while the intermediate layer is formed on the second surface of the substrate immediately after the surface treatment, the first surface of the substrate is exposed to the intermediate layer-drying temperature of the second surface after the surface treatment, and therefore the surface treatment effect becomes weak, and consequently, the difference between the surface resistance value of the second conductive layer and the surface resistance value of the first conductive layer appears in the conductive member.

While the surface treatment effect on the first surface of the substrate becomes weak, in the method for manufacturing a conductive member according to the third preferred embodiment of the invention, when the solid content application amount of the coating fluid for forming an intermediate layer in the step of forming the second intermediate layer is set in a range of two to three times of the solid content application amount of the coating fluid for forming an intermediate layer in the step of forming the first intermediate layer, it is possible to decrease the difference in the resistance value between both surfaces.

In the method for manufacturing a conductive member according to a fourth preferred embodiment of the invention, both the first surface and second surface of the substrate are surface-treated before the step of forming the first intermediate layer, and the solid content application amount of the coating fluid for forming a conductive layer in the step of forming the second conductive layer is set in a range of 1.25 times to 1.5 times of the solid content application amount of the coating fluid for forming a conductive layer in the step of forming the first conductive layer. Here, the above-described “solid content application amount” refers to the amount of components included in the coating fluid for forming a conductive layer other than the solvent.

The above-described method also offsets the difference in the resistance value between both surfaces.

In the method for manufacturing a conductive member according to a fifth preferred embodiment of the invention, both the first surface and second surface of the substrate are surface-treated before the step of forming the first intermediate layer, and the treatment amount (corona discharge amount, plasma irradiation amount, glow discharge amount or UV irradiation amount) for treating the surface (A surface), on which the second intermediate layer is formed, is set in a range of two to six times of the treatment amount for treating the surface (B surface), on which the first intermediate layer is formed.

The above-described method also offsets the difference in the resistance value between both surfaces. The reason therefor is not evident, but is considered as described below.

That is, it is considered that, while the intermediate layer is formed on the second surface of the substrate immediately after the surface treatment, the first surface of the substrate is exposed to the intermediate layer-drying temperature of the second surface after the surface treatment, and therefore the surface treatment effect becomes weak, and consequently, the difference between the surface resistance value of the second conductive layer and the surface resistance value of the first conductive layer appears in the conductive member. While the surface treatment effect on the first surface of the substrate becomes weak, when the treatment amount for treating the first surface (A surface) of the substrate is set in a range of two to six times of the treatment amount for treating the second surface (B surface) in advance, the difference in the resistance value between both surfaces is offset.

The above-described manufacturing method may also be combined with at least one of the methods employed in the manufacturing methods according to the second to fourth preferred embodiments.

The above-described difference in the resistance value between both surfaces rarely causes a problem in an ITO film manufactured on a glass substrate. This is because ITO is heated at a high temperature after being formed through sputtering or the like, and therefore the resistance value is determined by the change of ITO from amorphous to an aggregate of fine crystals, and both surfaces are heated at the same time. In addition, since an organic substance is not contained, it is not natural to think that some difference in the thermal history has an influence on the conductive characteristics. On the contrary, in the conductive layer including the conductive fiber in the matrix, the surface resistance value of the conductive layer is likely to be significantly changed due to the subtle change in the method for attaching the conductive fiber to the substrate using the surface energy of the substrate during coating or the aggregation state of the conductive fibers, or the deformation of the matrix due to heating in a case in which the matrix of an organic substance is used. The change in the surface resistance value increases as the conductive fiber is thinner, and the specific surface area increases. Therefore, it is difficult to obtain an industrially useful conductive member including conductive layers on both surfaces without the precise control of the conduction network of the conductive fiber using the above-described method and the decrease in the conductive property variation.

Thus far, the method for manufacturing a conductive member in a case in which the matrix in the conductive layer is a substance configured by including a three-dimensional crosslinking structure having the bond represented by the following general formula (I) has been described, and the method for manufacturing a conductive member in a case in which the matrix in the conductive layer is an organic polymer or a photoresist composition is the same as the method for manufacturing a conductive member in a case in which the matrix in the conductive layer is a substance configured by including a three-dimensional crosslinking structure having the bond represented by the following general formula (I) except for the fact that the step of forming the first conductive layer and the step of forming the second conductive layer are the following steps.

That is, both steps for forming the first and second conductive layers are steps in which a coated film is formed by applying a coating fluid for forming a conductive layer containing at least one selected from the group consisting of a conductive fiber having an average major axis length of 150 nm or less, an organic polymer, and a photoresist composition, and the coated film is dried through heating, thereby forming the first and second conductive layers.

<The Shape of the Conductive Layer>

In the conductive member according to the invention, the entire regions of the conductive layers on the front and back surfaces of the substrate form conductive regions. The above-described conductive member can be used as, for example, a transparent electrode in a solar cell.

The conductive member according to the invention has a characteristic of A/B being in a range of 1.0 to 1.2 when the surface resistance values of two conductive layers formed on the front and back surfaces of the substrate are represented by A and B respectively, and therefore the conductive member is preferably used to produce a pair of electrodes that are used in, for example, a touch panel since the effects of the invention can be obtained.

In a case in which the conductive member according to the invention is applied to the above-described electrodes, the conductive member is processed to provide a conductive region and a non-conductive region independently to each of the first and second conductive layers formed on the front and back surfaces of the substrate (hereinafter, the above-described conductive layer will also be referred to as “patterned conductive layer”). In this case, the conductive fiber may or may not be included in the non-conductive region. In a case in which the conductive fiber is included in the non-conductive region, the conductive fiber included in the non-conductive region is cut.

[Processing Method into the Patterned Conductive Layer]

To form the patterned conductive layer using the conductive member according to the invention, for example, the following processing methods are employed.

(1) A patterning method in which some of the metal nanowires are cut or removed by radiating a high energy laser beam such as carbon dioxide gas laser or a YAG laser to the metal nanowires included in a desired region in the conductive layer, thereby turning the desired region into the non-conductive region. The above-described method is described in, for example, JP2010-4496A.

(2) A patterning method in which a photoresist layer is provided on the conductive layer, a desired pattern is exposed and developed in the photoresist layer so as to form a resist in the desired pattern, and then the metal nanowires in the conductive layer in regions not protected by the resist are etched and removed using a wet process in which the metal nanowires are treated using an etchant capable of etching the metal nanowires or a dry process such as reactive ion etching. The above-described method is described in, for example, JP2010-507199T (particularly, paragraphs 0212 to 0217).

(3) A patterning method in which a conductive layer including the metal nanowires and a photoresist composition as the matrix is formed, a pattern is exposed and then developed using a developing liquid for the above-described photoresist composition on the conductive layer so as to remove the photoresist composition in the non-conductive region (the exposed region during the pattern exposure in the case of a positive-type photoresist or the non-exposed region during the pattern exposure in the case of a negative-type photoresist) and bring the metal nanowires present in the non-conductive region into an exposed state in which the metal nanowires are not protected by the photoresist composition (the exposed state refers to a state in which a fine exposed region is formed, that is, when only one of the metal nanowires is observed, a part of the metal nanowire is exposed), and subsequently the metal nanowires are treated using flowing water, high-pressure flush, or an etchant capable of etching the metal nanowires, thereby cutting the part of the metal nanowires present in the non-conductive region in the exposed state.

Meanwhile, in a case in which the patterned conductive layer is formed on a substrate for transfer, the patterned conductive layer is transferred to the substrate.

The light source used for the pattern exposure is selected in consideration of the photosensitive wavelength range of the photoresist composition, and generally, an ultraviolet ray such as a g-ray, an h-ray, an i-ray, or a j-ray is preferably used. In addition, a blue LED may be used.

The method for the pattern exposure is not particularly limited, and may be surface exposure using a photomask or scanning exposure using a laser beam or the like. At this time, refraction-type exposure using a lens may be employed, or reflection-type exposure using a reflecting mirror may be employed. It is also possible to use exposure methods such as contact exposure, proximity exposure, reduced size projection exposure, and reflection projection exposure.

Regarding the developing liquid, an appropriate developing liquid is selected depending on the photoresist composition. For example, in a case in which the photoresist composition is a photopolymerizable composition containing an alkali-soluble resin as a binder, an alkali aqueous solution is preferred.

The alkali contained in the alkali aqueous solution is not particularly limited, and can be appropriately selected depending on purposes. Examples of the alkali include tetramethylammonium hydroxide, tetraethyl ammonium hydroxide, 2-hydroxyethyltrimethylammonium hydroxide, sodium carbonate, sodium hydrogen carbonate, potassium carbonate, potassium hydrogen carbonate, sodium hydroxide, potassium hydroxide, and the like.

For the purpose of decreasing the development residue or optimizing the pattern shape, methanol, ethanol, or a surfactant may be added to the developing liquid. The surfactant can be selected for use from, for example, anionic surfactants, cationic surfactants, and nonioinic surfactants. Among the above-described surfactants, nonionic polyoxyethylene alkyl ether is particularly preferably added since the resolution increases.

The method for supplying the alkali solution is not particularly limited, and can be selected depending on purposes. Examples thereof include coating, immersion, spraying, and the like. Specific examples include dip development in which a substrate including an exposed photosensitive layer or a substrate is immersed in an alkali solution, paddle development in which a developing liquid is stirred during immersion, shower development in which a developing liquid is showered or sprayed, a development method in which the surface of a photosensitive layer is rubbed with a sponge or a fiber bundle soaked with an alkali solution. Among the above-described methods, a method in which a substrate is immersed in an alkali solution is particularly preferred.

The immersion time in the alkali solution is not particularly limited, and can be selected depending on purposes, but is preferably in a range of 10 seconds to 5 minutes.

The solution dissolving the metal nanowires can be appropriately selected depending on the metal nanowires. In a case in which the metal nanowires are silver nanowires, examples thereof include a bleaching fixing liquid, a strong acid, an oxidant, hydrogen peroxide, and the like that are used in the bleaching and fixing step of developing paper of, mainly, a halogenated silver color photosensitive material in a so-called photographic science field. Among the above-described solutions, a bleaching fixing liquid, diluted nitric acid, and hydrogen peroxide are particularly preferred. Meanwhile, when the silver nanowires are dissolved using the solution dissolving the metal nanowires, the silver nanowires in a portion supplied with the solution may not be fully dissolved, or some of the silver nanowires may remain as long as the silver nanowires are not conductive.

The concentration of the diluted nitric acid is preferably in a range of 1 mass % to 20 mass %.

The concentration of the hydrogen peroxide is preferably in a range of 3 mass % to 30 mass %.

As the bleaching fixing liquid, for example, the treatment materials or treatment methods described in row 1 of the bottom right column on page 26 to row 9 in the top right column on page 34 of JP1990-207250A (JP-H2-207250A) and in row 17 of the top left column on page 5 to row 20 in the bottom right column on page 18 of JP1992-97355A (JP-H4-97355A) can be preferably applied.

The bleaching fixing time is preferably 180 seconds or shorter, more preferably in a range of 1 second to 120 seconds, and still more preferably in a range of 5 seconds to 90 seconds. In addition, the water-washing or stabilizing time is preferably 180 seconds or less, and more preferably in a range of 1 second to 120 seconds.

The bleaching fixing liquid is not particularly limited as long as the bleaching fixing liquid is a photograph bleaching fixing liquid, and can be appropriately selected depending on purposes. Examples thereof include CP-48S, CP-49E (bleaching fixing agents for color paper) manufactured by Fiji Film Corporation, an EKTACOLOR RA bleaching fixing liquid manufactured by Kodak Japan Ltd., bleaching fixing liquids D-J2P-02-P2, D-30P2R-01, D-22P2R-01 manufactured by Dai Nippon Printing Co., Ltd., and the like. Among the above-described bleaching fixing liquids, CP-48S and CP-49E are particularly preferred.

The viscosity of the solution dissolving the metal nanowires is preferably in a range of 5 mPa·s to 300,000 mPa·s, and more preferably in a range of 10 mPa·s to 150,000 mPa·s at 25° C. When the viscosity is set to 5 mPa·s, it becomes easy to control the diffusion of the solution within a desired range, and a pattern in which boundaries between the conductive regions and the non-conductive regions are clear is ensured. On the other hand, when the viscosity is set to 300,000 mPa·s or less, the load-free printing of the solution is ensured, and it is possible to complete necessary treatments for the dissolution of the metal nanowires within a desired time.

The supply of the solution dissolving the metal nanowires in a pattern is not particularly limited as long as the solution can be supplied in a pattern, and can be appropriately selected depending on purposes. Examples thereof include screen printing, ink jet printing, a method in which an etching mask is formed in advance using a resist agent or the like, and the solution is applied on the etching mask through coater application, roller application, dipping application, or spray application. Among the above-described methods, screen printing, ink jet printing, coater application, and dip (immersion) application are particularly preferred.

As the ink jet printing, for example, any one of the piezo ink jet printing and the thermal ink jet printing can be used.

The type of the pattern is not particularly limited, and can be appropriately selected depending on purposes. Examples of the pattern type include a letter, a symbol, a shape, a figure, a wiring pattern, and the like.

The size of the pattern is not particularly limited, and can be appropriately selected depending on purposes, and may be any size in a range of nanomillimeters to millimeters.

The conductive member according to the invention is preferably adjusted so that the surface resistance value of the conductive layer reaches 1000 Ω/square or less.

The above-described surface resistance value is a value obtained by measuring the surface of the conductive layer in the conductive member according to the invention using a four-point probe method. The method for measuring the surface resistance value using the four-point probe method is capable of measuring the surface resistance value based on, for example, JIS K 7194:1994 (Testing method of resistivity of conductive plastics with a four-point probe array) or the like, and is capable of easily measuring the surface resistance value using a commercially available surface resistance value meter. To set the surface resistance value to 1,000 Ω/square or less, it is necessary to adjust at least one of the type and content of the metal nanowires included in the conductive layer and the type and content of the matrix.

The surface resistance value of the conductive member according to the invention is more preferably set in a range of 0.1 Ω/square to 900 Ω/square.

The conductive member according to the invention has excellent transparency and film strength, and has a ratio (the above-described A/B) of the surface resistance value between two conductive layers formed on the front and back surface of the substrate in a range of 1.0 to 1.2.

The conductive member according to the invention is widely applied to, for example, a touch panel, an electrode for a display, an electromagnetic wave shield, an electrode for an organic EL display, an electrode for an inorganic EL display, electronic paper, an electrode for a flexible display, an integrated solar cell, a liquid crystal display apparatus, a touch panel function-equipped display apparatus, a variety of other devices, and the like. Among the above-described devices, the conductive member is particularly preferably applied to a touch panel.

<<Touch Panel>>

A conductive element produced by patterning the conductive layer in the conductive member according to the invention is used as, for example, a surface capacitive touch panel, a projected capacitive touch panel, a resistive touch panel, and the like. Here, the touch panel includes so-called touch sensors and touch pads.

The surface capacitive touch panel is described in, for example, JP2007-533044T.

In a case in which the conductive member according to the invention is used in a touch panel, the thickness of the conductive member is preferably in a range of 30 μm to 200 μm due to a decrease in the film thickness of a touch panel module and the ease of handling the conductive member.

### EXAMPLES

Hereinafter, examples of the invention will be described, but the invention is not limited to the examples. Meanwhile, “%” and “parts” used as the unit of the content ratio in the examples are both based on mass.

In the following examples, the average diameter (average minor axis length), average major axis length, variation coefficient of the minor axis, and aspect ratio of the conductive fiber (metal nanowires) were measured as described below.

<The Average Diameter (Average Minor Axis Length) and Average Major Axis Length of the Metal Nanowires>

The diameters (minor axis lengths) and major axis lengths of 300 metal nanowires randomly selected from metal nanowires observed in an enlarged manner using a transmission electron microscope (TEM; manufactured by JEOL Ltd., JEM-2000FX), and the average diameter (minor axis length) and average major axis length of the metal nanowires were obtained from the average values.

<The Variation Coefficient of the Minor Axis Length (Diameter) of the Metal Nanowires>

The minor axis lengths (diameters) of 300 nanowires randomly selected from the above-described transmission electron microscope (TEM) image were measured, and the standard deviation and average value of the 300 nanowires were calculated, thereby obtaining the variation coefficient of the minor axis length (diameter) of the metal nanowires.

<Aspect Ratio>

The aspect ratio was obtained by dividing the above-described average major axis length of the metal nanowires by the average diameter (minor axis length).

### Preparation Example 1

### The Preparation of a Metal (Silver) Nanowire Dispersion Liquid (1)

The following addition liquids A, B, C, and D were prepared in advance.

[Addition Liquid A]

60 mg of stearyl trimethyl ammonium chloride, 6.0 g of a 10% aqueous solution of strearyl trimethyl ammonium hydroxide, and 2.0 g of glucose were dissolved in 120.0 g of distilled water, thereby obtaining a reaction solution A-1. Separately, 70 mg of silver nitrate powder were dissolved in 2.0 g of distilled water, thereby obtaining a silver nitrate aqueous solution A-1. The reaction solution A-1 was kept at 25° C., and the silver nitrate aqueous solution A-1 was added under fast stirring.

The fast stirring was continued over 180 minutes from the addition of the silver nitrate aqueous solution A-1, thereby obtaining an addition liquid A.

[Addition Liquid B]

42.0 g of silver nitrate powder was dissolved in 958 g of distilled water.

[Addition Liquid C]

75 g of 25% ammonia water was mixed with 925 g of distilled water.

[Addition Liquid D]

400 g of polyvinyl pyrrolidone (K30) was dissolved in 1.6 kg of distilled water.

Next, a silver nanowire dispersion liquid (1) was prepared in the following manner. 1.30 g of stearyl trimethyl ammonium bromide powder, 33.1 g of sodium bromide powder, 1,000 g of glucose powder, and 115.0 g of nitric acid (1 N) were dissolved in 12.7 kg of distilled water at 80° C. The solution was kept at 80° C., and the addition liquids A, B, and C were sequentially added at addition rates of 250 cc/minute, 500 cc/minute, and 500 cc/minute respectively under stirring at 500 rpm. After the addition, the solution was heated and stirred at 80° C. for 100 minutes from the setting of the stirring rate to 200 rpm, and the solution was cooled to 25° C. After that, the stirring rate was changed to 500 rpm, and the addition liquid D was added at 500 cc/minute. The liquid was used as a preliminary liquid 101.

Next, the preliminary liquid 101 was added at once to 1-propanol under fast stirring so that the volume ratio reached one-to-one in terms of the mixing ratio. After the addition, the obtained solution mixture was stirred over three minutes, and was used as a preliminary liquid 102.

Ultrafiltration was carried out in the following manner using an ultrafiltration module having a molecular weight cutoff of 150,000. After the concentration of the preliminary liquid 102 was condensed to four times, the addition and condensation of a solution mixture (volume ratio of one-to-one) of distilled water and 1-propanol were repeated until the conductivity of the filtrate finally reached 50 μS/cm or less, and a silver nanowire dispersion liquid (1) having a metal content of 0.45% was obtained.

Regarding silver nanowires in the obtained silver nanowire dispersion liquid (1), the average minor axis length, the average major axis length, the variation coefficient of the minor axis length of the silver nanowires, and the average aspect ratio were measured as described above.

As a result, the average minor axis length was 18.6 nm, the average major axis length was 8.2 μm, and the variation coefficient was 15.0%. The average aspect ratio was 440. Hereinafter, the “silver nanowire dispersion liquid (1)” denoted below will refer to the silver nanowire dispersion liquid obtained using the above-described method.

The variation coefficient is obtained by “the standard deviation of the diameter/the average of the diameter”.

### The Preparation of a Silver Nanowire Dispersion Liquid (2)

A silver nanowire dispersion liquid (2) having a metal content of 0.45% was obtained in the same manner as in Preparation Example 1 except that 130.0 g of distilled water was used instead of the addition liquid A in Preparation Example 1.

Regarding silver nanowires in the obtained silver nanowire dispersion liquid (2), the average minor axis length, the average major axis length, the variation coefficient of the minor axis length of the silver nanowires, and the average aspect ratio were measured as described above. As a result, the average minor axis length was 47.2 nm, the average major axis length was 12.6 μm, and the variation coefficient was 23.1%. The average aspect ratio was 267. Hereinafter, the “silver nanowire dispersion liquid (2)” denoted below will refer to the silver nanowire dispersion liquid obtained using the above-described method.

### The Preparation of a Silver Nanowire Dispersion Liquid (3)

The silver nanowire dispersion liquid described in Examples 1 and 2 in US2011/0174190A1 (paragraph 0151 on page 8 to paragraph 0160 on page 9) was prepared, and was diluted using distilled water, thereby obtaining a 0.45% silver nanowire dispersion liquid (3).

Regarding silver nanowires in the obtained silver nanowire dispersion liquid (3), the average minor axis length, the average major axis length, the variation coefficient of the minor axis length of the silver nanowires, and the average aspect ratio were measured as described above. As a result, the average minor axis length was 29 nm, the average major axis length was 16 μm, and the variation coefficient was 16.2%. The average aspect ratio was 552. Hereinafter, the “silver nanowire dispersion liquid (3)” denoted below will refer to the silver nanowire dispersion liquid obtained using the above-described method.

### Preparation Example 2

### The Production of a PET Substrate

Solutions for adhesion 1 and 2 were prepared using the following formulations.

[Solution for Adhesion 1]

| | | |
|---|---|---|
| TAKELAC WS-4000 | 5.0 | parts |
| (polyurethane for coating, solid content concentration | | |
| 30%, manufactured by Mitsui Chemicals, Inc.) | | |
| Surfactant | 0.3 | parts |
| (NAROACTY HN-100, manufactured by Sanyo Chemical | | |
| Industries, Ltd.) | | |
| Surfactant | 0.3 | parts |
| (SANDET BL, solid content concentration 43%, | | |
| manufactured by Sanyo Chemical Industries, Ltd.) | | |
| Water | 94.4 | parts |

[Solution for Adhesion 2]

| | | |
|---|---|---|
| Tetraethoxysilane | 5.0 | parts |
| (KBE-04, manufactured by Shin-Etsu Chemical, | | |
| Co., Ltd.) | | |
| 3-glycidoxypropyltrimethoxysilane | 3.2 | parts |
| (KBM-403, manufactured by Shin-Etsu Chemical, | | |
| Co., Ltd.) | | |
| 2-(3,4-epoxycylohexyl)ethyltrimethoxysilane | 1.8 | parts |
| (KBM-303, manufactured by Shin-Etsu Chemical, | | |
| Co., Ltd.) | | |
| Acetic acid aqueous solution (acetic acid | 10.0 | parts |
| concentration = 0.05%, pH = 5.2) | | |
| Curing agent | 0.8 | parts |
| (boric acid, manufactured by Wako Pure Chemical, | | |
| Industries, Ltd.) | | |
| Colloidal silica | 60.0 | parts |
| (SNOWTEX O, average particle diameter: 10 nm to | | |
| 20 nm, solid content concentration: 20%, pH = | | |
| 2.6, manufactured by Nissan Chemical Industries, Ltd.) | | |
| Surfactant | 0.2 | parts |
| (NAROACTY HN-100, manufactured by Sanyo Chemical | | |
| Industries, Ltd.) | | |
| Surfactant | 0.2 | parts |
| (SANDET BL, solid content concentration 43%, | | |
| manufactured by Sanyo Chemical Industries, Ltd.) | | |

The solution for adhesion 2 was prepared as described below.

3-glycidoxypropyltrimethoxysilane was added dropwise to the acetic acid aqueous solution under fast stirring over three minutes, thereby obtaining an aqueous solution 1. Next, 2-(3,4-epoxycylohexyl)ethyltrimethoxysilane was added to the aqueous solution 1 under fast stirring over three minutes, thereby obtaining an aqueous solution 2. Next, tetramethoxysilane was added to the aqueous solution 2 under fast stirring over five minutes, and then stirring was continued for two hours, thereby obtaining an aqueous solution 3. Next, the colloidal silica, the curing agent, and the surfactants were sequentially added to the aqueous solution 3, thereby preparing a solution for adhesion 2.

### Example 1

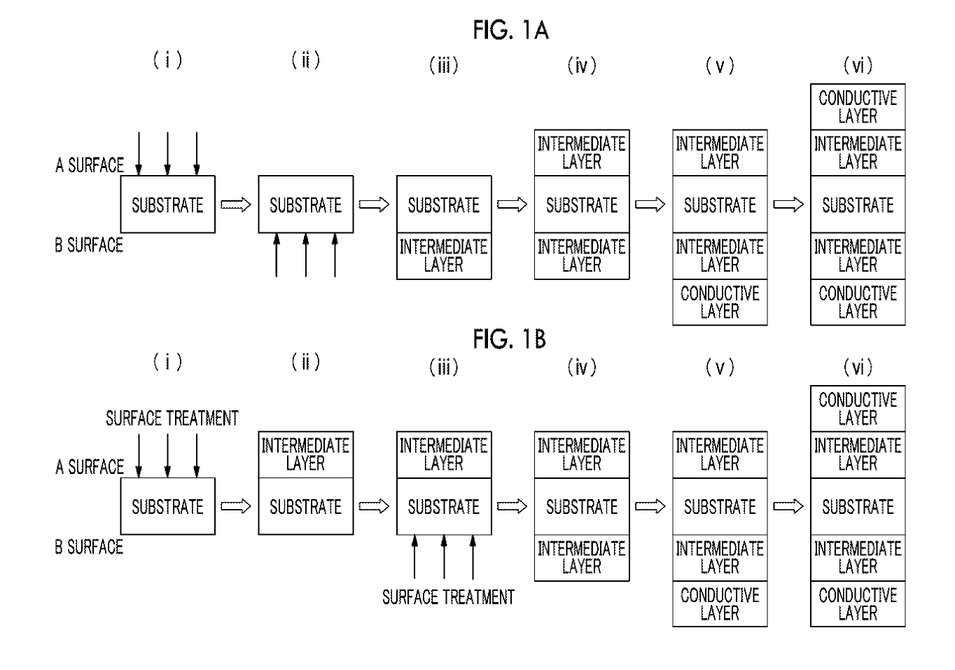

A conductive member according to Example 1 was produced using processes described below. Meanwhile, the order of the processes was indicated using an order of the respective processes (i) to (vi) for “Example 1” in Table 1 described below, and schematic cross-sectional views immediately after the respective processes were illustrated in FIG. 1A.

A corona discharging treatment of 1 J/m² was sequentially carried out on the first surface (hereinafter, also referred to as “A surface”) and the second surface (hereinafter, also referred to as “B surface”) of a 125 μm-thick PET film. After that, first, the solution for adhesion 1 was applied to the A surface, was dried at 120° C. for two minutes, then, the same processes were carried out on the B surface in the same order, thereby forming 0.11 μm-thick adhesive layers 1 on the A surface and B surface of the PET film respectively.

Next, a corona discharging treatment of 1 J/m² was sequentially carried out on the first surface and second surface of the PET substrate supplied with the above-described adhesive layer 1. After that, first, the solution for adhesion 2 was applied to the A surface, was dried at 170° C. for one minute, then, the same processes were carried out on the B surface in the same order, thereby forming 0.5 μm-thick adhesive layers 2 on the A surface and B surface of the PET film respectively.

A coating fluid for forming an intermediate layer was prepared using the following formulation.

[Coating fluid for forming an intermediate layer]

| | |
|---|---|
| N-(2-aminoethyl)-3-aminopropyltrimethoxysilane | 0.02 parts |
| Distilled water | 99.8 parts |

The coating fluid for forming an intermediate layer was prepared by adding water to N-(2-aminoethyl)-3-aminopropyltrimethoxysilane, and stirring the mixture for one hour.

After a corona discharging treatment was carried out on the surfaces of the adhesive layers on the A surface and B surface under the conditions described in Table 2, the coating fluid for forming an intermediate layer was applied to the adhesion layer on the B surface using a bar coating method, and the coating fluid was heated and dried for one minute under the conditions described in Table 2, thereby forming a 1 nm-thick first intermediate layer. Next, the same processes were carried out on the A surface in the same order, thereby forming a 1 nm-thick second intermediate layer.

Next, a coating fluid for forming a conductive layer prepared as described below was applied to the first intermediate layer provided on the B surface using a slot die coater having an extrusion-type application head equipped with a backup roller, which was exemplified in JP2006-95454A, so that the silver amount reached 0.017 g/m², and the total solid content application amount reached 0.128 g/m², and then a sol-gel reaction was caused for one minute under the film-forming conditions described in Table 2, thereby forming a first conductive layer on the B surface.

Here, the clearance between the die tip section and the supporter application surface was set to 50 μm, the depressurization degree of the upper stream against the downstream of the coating fluid bead section was set to 30 Pa, the line speed was set to 10 m/minutes, and the wet coating amount was set to 13 cc/m².

[The Preparation of the Coating Fluid for Forming a Conductive Layer]

A solution of an alkoxide compound having the following composition was stirred at 60° C. for one hour, and it was checked whether or not the solution became homogeneous. 3.44 parts of the obtained sol-gel solution and 16.56 parts of the “silver nanowire dispersion liquid (1)” obtained in Preparation Example 1 were mixed, and furthermore, were diluted using 72.70 parts of distilled water, thereby obtaining a coating fluid for forming a conductive layer.

<The Solution of an Alkoxide Compound>

| | | |
|---|---|---|
| Tetraethoxysilane(compound II) | 5.0 | parts |
| (KBE-04, manufactured by Shin-Etsu Chemical, Co., Ltd.) | | |
| 1% aqueous solution of acetic acid | 10.0 | parts |
| Distilled water | 4.0 | parts |

Next, the coating fluid for forming a conductive layer was applied to the second intermediate layer provided on the A surface using the slot die coater so that the silver amount reached 0.017 g/m², and the total solid content application amount reached 0.128 g/m², and then a sol-gel reaction was caused for one minute at the conductive layer-forming temperature described in Table 2, thereby forming a second conductive layer on the A surface.

Therefore, a conductive member of Example 1 was obtained. The mass ratio of the compound (II)/the conductive fiber in the first and second conductive layers were 6.5/1.

<Patterning>

A patterning treatment was carried out on the above-obtained conductive member using the following method. A WHT-3. and SQUEEGEE No. 4 YELLOW manufactured by Mino Group Co., Ltd were used for screen printing. Regarding a solution of silver nanowires for forming a pattern, a CP-48S-A liquid, a CP-48S-B liquid (both manufactured by FujiFilm Corporation), and pure water were mixed at 1:1:1, and the viscosity of the mixture was increased using hydroxymethyl cellulose, thereby obtaining an ink for screen printing. A pattern mesh having a stripe pattern (line/space=50 μm/50 μm) was used. The patterning treatment was carried out, and a conductive layer including a conductive region and a non-conductive region was formed.

### Comparative Example 1

A conductive member of Comparative Example 1 was obtained in the same manner as in Example 1 except that the conductive member was produced in the order of the processes (i) to (vi) described for “Comparative Example 1” in the following table 1. Meanwhile, schematic cross-sectional views immediately after the respective processes were illustrated in FIG. 1B.

TABLE 1

| | Surface | | Intermediate | | | |
|---|---|---|---|---|---|---|
| Example/ | treatment | | layer | | Conductive layer | |
| Comparative | A | B | A | B | A | |
| Example | surface | surface | surface | surface | surface | B surface |
| Example 1 | (i) | (ii) | (iv) | (iii) | (vi) | (v) |
| Comparative | (i) | (iii) | (ii) | (iv) | (vi) | (v) |
| Example 1 | | | | | | |

### Examples 2 to 6

Conductive members of Examples 2 to 6 were obtained in the same manner as in Example 1 except for the facts that the radiation amount of the corona discharging carried out on the A surface and B surface of the substrate, the solid content application amount and intermediate layer-drying temperature of the coating fluid for forming an intermediate layer provided on the A surface and the B surface, and the solid content application amount and conductive layer-forming temperature of the coating fluid for forming a conductive layer provided on the A surface and the B surface were changed as described in Table 2.

For the obtained conductive members of Examples 1 to 6 and Comparative Example 1, the surface resistance values, haze, and film strength of both surfaces were measured using the following measurement methods, and the evaluation results based on the following evaluation criteria were described in Table 2. Furthermore, the ratios (A/B) of the conductive layers on both surfaces were also described in Table 2. Meanwhile, regarding the A and B values, as described above, the resistance value of the surface having a greater numeric value of the resistances of both surfaces was considered as A, and that of the surface having a smaller numeric value was considered as B.

<Surface Resistance Value>

The surface resistance values of the conductive layers were measured using a Loresta-GP MCP-T600 manufactured by Mitsubish Chemical Corporation, and were ranked according to the following criteria.

The resistance value was measured by measuring the resistance values at total ten places, that is, five places determined by equally dividing the conductive region in the sample in the width direction and five places determined by equally dividing the conductive region in the longitudinal direction, and obtaining the average value. The resistance values of both surfaces were measured under the same conditions using the same method.

The resistance values were measured before and after the patterning respectively, and it was confirmed that the resistance values satisfied the following ranks before and after the patterning.

Regarding the resistance value of the patterning sample, it is difficult to measure the resistance value from the actual conductive section in a fine pattern, and therefore a pattern for evaluation (100 mm square) was provided in the same sample as the actual pattern, and the resistance of the conductive section was measured. The above-described processes were carried out at five places, and the average value was obtained.
Rank 4: an excellent level having a surface resistance value in a range of 30 Ω/square to less than 60 Ω/square.
Rank 3: a permissible level having a surface resistance value in a range of 60 Ω/square to less than 200 Ω/square.
Rank 2: a level of a slight practical problem having a surface resistance value in a range of 200 Ω/square to less than 1000 Ω/square.
Rank 1: a level of a practical problem having a surface resistance value of 1000 Ω/square or more.

<Optical Characteristic (Haze)>

The haze of a rectangular beta exposed region on the obtained conductive film was measured using a HAZE GARD PLUS manufactured by BYK-Gardner GmbH, and were ranked according to the following criteria.

Regarding the haze of the patterning sample, it is difficult to measure the haze from the actual conductive section in a fine pattern, and therefore a pattern for evaluation (100 mm square) was provided in the same sample as the actual pattern, and the haze of the conductive section was measured.
Rank A: an excellent level having a haze of less than 1.5%.
Rank B: a favorable level having a haze in a range of 1.5% to less than 2.0%.
Rank C: a level of a slight practical problem having a haze in a range of 2.0% to less than 2.5%.
Rank D: a level of a practical problem having a haze of 2.5% or more.

<Film Strength>

After the film was scratched across a length of 10 mm under a condition of a load of 500 g using a pencil scratch hardness tester (manufactured by Toyo seiki seisakusho, NP type) in which a pencil for pencil scratching (hardness HB and hardness B) inspected by Japan Paint Inspection and Testing Association was set according to JIS K5600-5-4, the scratched portions were observed using a digital microscope (VHX-600, manufactured by Keyence Corporation, magnification of 2,000 times), and the film strength was ranked according to the following criteria. Meanwhile, Rank 3 or higher are problem-free levels at which, practically, the cutting of the conductive film was not observed, and the conductive property can be ensured.

[Evaluation Criteria]
Rank 4: an extremely favorable level at which no scratch trace was observed after the scratching using the hardness 2H pencil.
Rank 3: a favorable level at which the conductive fiber was cut, but the conductive property did not change after the scratching using the hardness 2H pencil.
Rank 2: a level of a practical problem at which the conductive fiber was cut, and the conductive property degraded in a partial region of the conductive layer after the scratching using the hardness 2H pencil.
Rank 1: a level of a practical problem at which the conductive fiber was cut, and the conductive property degraded in a majority region of the conductive layer after the scratching using the hardness 2H pencil.

TABLE 2

| | Base material | | Intermediate layer | | | | Conductive layer | | | |
|---|---|---|---|---|---|---|---|---|---|---|
| | Surface | | Intermediate | | Solid content | | Conductive | | Solid content | |
| | treatment | | layer-drying | | application | | layer-forming | | application | |
| | conditions | | temperature | | amount | | temperature | | amount | |
| | (J/m²) | | (° C.) | | (mg/m²) | | (° C.) | | (mg/m²) | |
| | A | B | A | B | A | B | A | B | A | B |
| | surface | surface | surface | surface | surface | surface | surface | surface | surface | surface |
| Example 1 | 1 | 1 | 120 | 120 | 1 | 1 | 120 | 120 | 17 | 17 |
| Example 2 | 1 | 1 | 120 | 80 | 1 | 1 | 120 | 80 | 17 | 17 |
| Example 3 | 1 | 1 | 100 | 80 | 1 | 1 | 100 | 80 | 17 | 17 |
| Example 4 | 2 | 1 | 120 | 120 | 1 | 1 | 120 | 120 | 17 | 17 |
| Example 5 | 1 | 1 | 120 | 120 | 2.1 | 1 | 120 | 120 | 17 | 17 |
| Example 6 | 1 | 1 | 120 | 120 | 1 | 1 | 120 | 120 | 22.5 | 17 |
| Comparative | 1 | 1 | 120 | 120 | 1 | 1 | 120 | 120 | 17 | 17 |
| Example 1 | | | | | | | | | | |

| | Evaluation result | | | | | | |
|---|---|---|---|---|---|---|---|
| | Evaluation | | | | | | |
| | rank of | | Ratio of surface | Evaluation | | Evaluation | |
| | surface resistance | | resistance value | rank of | | rank of | |
| | value | | between front surface | haze | | film strength | |
| | A | B | and back surface | A | B | A | B |
| | surface | surface | A/B | surface | surface | surface | surface |
| Example 1 | 3 | 4 | 1.15 | A | A | 3 | 4 |
| Example 2 | 4 | 4 | 1.03 | A | A | 4 | 4 |
| Example 3 | 4 | 4 | 1.05 | A | A | 3 | 3 |
| Example 4 | 4 | 4 | 1.07 | A | A | 4 | 4 |
| Example 5 | 4 | 4 | 1.07 | A | A | 3 | 4 |
| Example 6 | 4 | 4 | 1.00 | B | A | 2 | 4 |
| Comparative | 2 | 4 | >1.5 | A | A | 1 | 4 |
| Example 1 | | | | | | | |

From the results in Table 2, it is found that, in the conductive member according to the invention, the ratio (A/B) of the surface resistance value between the respective conductive layers formed on the front surface and the back surface is less than 1.2. Particularly, it is found that, in the conductive member of Example 2 in which the intermediate layer-drying temperature and conductive layer-forming temperature of the B surface were set to a temperature lower than those of the A surface by 40° C., and the conductive member of Example 4 in which the corona discharging treatment amount for treating the A surface of the substrate was set to twice of that of the B surface, the ratio (A/B) of the surface resistance value was less than 1.1, and the most favorable performances were exhibited in terms of the haze and the film strength.

### Examples 7 to 15 and Comparative Examples 2 to 10

Conductive members of Examples 7 to 15 were produced in the same manner as in Example 1 except that the compounds of Examples 7 to 15 described in Table 3 were used in the same amount instead of tetraethoxysilane in the solution of the alkoxide compound used for the preparation of the coating fluid for forming a conductive layer in Example 1.

Furthermore, conductive members of Comparative Examples 2 to 10 were produced in the same manner as in Comparative Example 1 except that the compounds of Comparative Examples 2 to 10 described in Table 3 were used in the same amount instead of tetraethoxysilane in the solution of the alkoxide compound used for the preparation of the coating fluid for forming a conductive layer in Comparative Example 1.

For the obtained conductive members, the surface resistance values of the conductive layers on the A surface and the B surface and the A/B ratios were evaluated in the same manner as in Example 1, and the evaluation results were described in Table 3.

TABLE 3

| | | Evaluation result | | |
|---|---|---|---|---|
| | | | | Ratio of surface |
| | | Evaluation rank | | resistance value |
| | | of surface | | between front |
| Example/ | | resistance value | | surface and |
| Comparative | Specific alkoxide compound used for | A | B | back surface |
| Example | the preparation of matrix | surface | surface | A/B |
| Example 7 | 3-glycidoxy propyl trimethoxysilane | 3 | 4 | 1.11 |
| Example 8 | Diethyl dimethoxysilane | 3 | 4 | 1.17 |
| Example 9 | Tetramethoxysilane | 3 | 4 | 1.15 |
| Example 10 | Ureidopropyl triethoxysilane | 3 | 4 | 1.15 |
| Example 11 | Tetrapropoxy titanate | 3 | 4 | 1.15 |
| Example 12 | Tetraethoxy zirconate | 3 | 4 | 1.18 |
| Example 13 | Mixture of 3-glycidoxypropyltrimethoxysilane | 3 | 4 | 1.13 |
| | and tetraethoxysilane | | | |
| | (mass ratio = 1:1) | | | |
| Example 14 | Mixture of 3-glycidoxypropyltrimethoxysilane | 3 | 4 | 1.12 |
| | and tetraethoxysilane | | | |
| | (mass ratio = 1:4) | | | |
| Example 15 | Mixture of 3-glycidoxypropyltrimethoxysilane | 3 | 4 | 1.14 |
| | and tetraethoxysilane | | | |
| | (mass ratio = 4:1) | | | |
| Comparative | 3-glycidoxypropyltrimethoxysilane | 2 | 4 | >1.5 |
| Example 2 | | | | |
| Comparative | Diethyl dimethoxysilane | 2 | 4 | >1.5 |
| Example 3 | | | | |
| Comparative | Tetramethoxysilane | 2 | 4 | >1.5 |
| Example 4 | | | | |
| Comparative | Ureidopropyl triethoxysilane | 2 | 4 | >1.5 |
| Example 5 | | | | |
| Comparative | Tetrapropoxy titanate | 2 | 4 | >1.5 |
| Example 6 | | | | |
| Comparative | Tetraethoxy zirconate | 2 | 4 | >1.5 |
| Example 7 | | | | |
| Comparative | Mixture of 3-glycidoxypropyltrimethoxysilane | 2 | 4 | >1.5 |
| Example 8 | and tetraethoxysilane | | | |
| | (mass ratio = 1:1) | | | |
| Comparative | Mixture of 3-glycidoxypropyltrimethoxysilane | 2 | 4 | >1.5 |
| Example 9 | and tetraethoxysilane | | | |
| | (mass ratio = 1:4) | | | |
| Comparative | Mixture of 3-glycidoxypropyltrimethoxysilane | 2 | 4 | >1.5 |
| Example 10 | and tetraethoxysilane | | | |
| | (mass ratio = 4:1) | | | |

From the results in Table 3, it is found that, even when a different alkoxide compound was used when the coating fluid for forming a conductive layer was prepared, similar to the case of Example 1, a conductive member having a ratio of the surface resistance value between the conductive layers on the front surface and the back surface of less than 1.2 was obtained.

### Examples 16 to 19 and Comparative Examples 11 to 14

### The Preparation of the Coating Fluid for Forming a Conductive Layer Containing a Photoresist Composition as the Matrix

—The Preparation of a Silver Nanowire Solvent-Dispersed Substance—

A step in which propylene glycol monomethyl ether was added to the silver nanowire aqueous dispersed substance used in Example 1, and centrifugal separation was carried out, thereby removing the supernatant liquid was repeatedly carried out three times, and ultimately, propylene glycol monomethyl ether was added, thereby preparing 0.8 mass % of a silver nanowire solvent-dispersed substance.

—The Synthesis of a Binder (A-1)—

7.79 g of methacrylic acid and 37.21 g of benzyl methacrylate were used as monomer components configuring a copolymer, 0.5 g of azobisisobutyronitrile was used as a radical polymerization initiator, and a polymerization reaction of the above-described components was caused in 55.00 g of propylene glycol monomethyl ether acetate (PGMEA), thereby obtaining a PGMEA solution (solid content concentration: 40 mass %) of a binder (A-1) having the following structure. Meanwhile, the polymerization temperature was adjusted to a temperature in a range of 60° C. to 100° C.

As a result of measuring the molecular weight using gel permeation chromatography (GPC), the weight-average molecular weight (Mw) in terms of polystyrene was 30,000, and the molecular weight distribution (Mw/Mn) was 2.21.

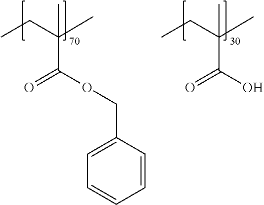

—The Synthesis of a Binder P-1—

8.57 parts of 1-methoxy-2-propanol (MMPGAC, manufactured by Daicel Corporation) was added to a reaction container and heated to 90° C. in advance, and a solution mixture made up of, as monomers, 6.27 parts of isopropyl methacrylate, 5.15 parts of methacrylic acid, 1 part of an azo-based polymerization initiator (manufactured by Wako Pure Chemical, Industries, Ltd., V-601), and 8.57 parts of 1-methoxy-2-propanol was added dropwise to the reaction container at 90° C. over two hours under a nitrogen gas atmosphere. After the dropwise addition, a reaction was caused for four hours, thereby obtaining an acryl resin solution.

Next, 0.025 parts of hydroquinone monomethyl ether and 0.084 parts of tetraethyl ammonium bromide were added to the acryl resin solution, and 5.41 parts of glycidyl methacrylate was added dropwise over two hours. After the dropwise addition, a reaction was caused at 90° C. for four hours under the blow-in of air, and then 1-methoxy-2-propanol was added so that the solid content concentration reached 45%, thereby obtaining a 45% 1-methoxy-2-propanol solution of a water-insoluble binder P-1 (acid value: 73 mgKOH/g, Mw: 10,000).

Meanwhile, the average molecular weight Mw of the resin P-1 was measured using GPC

—The Preparation of a Photoresist Composition—

—The Preparation of a Photoresist Composition (1)—

4.19 parts (solid content 40.0%) of the PGMEA solution of the binder (A-1), 0.95 parts of TAS-200 (esterification rate: 66%, manufactured by Toyo Gosei Co., Ltd.) represented by the following structural formula as a photosensitive compound, 0.80 parts of EHPE-3150 (manufactured by Daicel Corporation) as a crosslinking agent, and 19.06 parts of PGMEA were added and stirred, thereby preparing a photoresist composition (1).

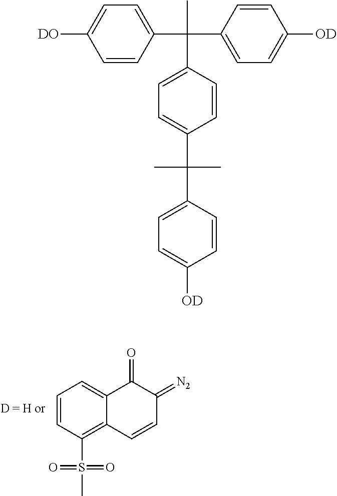

—The Preparation of a Photoresist Composition (2)—

3.80 parts (solid content 40.0%) of the PGMEA solution of the binder (A-1), 1.59 parts of KAYARAD DPHA (manufactured by Nippon Kayaku Co., Ltd.) as a polymerizable compound, 0.159 parts of IRGACURE 379 (manufactured by Ciba Specialty Chemicals) as a photopolymerization initiator, 0.150 parts of EHPE-3150 (manufactured by Daicel Corporation) as a crosslinking agent, 0.002 parts of MEGAFAC F781F (manufactured by DIC Corporation) as a surfactant, and 19.3 parts of PGMEA were added and stirred, thereby preparing a photoresist composition (2).

<The Preparation of a Photoresist Composition (3)>

4.50 parts (solid content 40.0%) of the PGMEA solution of the binder (A-1), 1.00 part of 2-ethylhexylate as a polymerizable compound, 1.00 part of trimethylolpropane triacrylate (TMPTA) as a polymerizable compound, 0.2 parts of IRGACURE 379 (manufactured by Ciba Specialty Chemicals) as a photopolymerization initiator, 0.150 parts of EHPE-3150 (manufactured by Daicel Corporation) as a crosslinking agent, 0.002 parts of MEGAFAC F781F (manufactured by DIC Corporation) as a surfactant, and 19.3 parts of PGMEA were added and stirred, thereby preparing a photoresist composition (3).

—The Production of a Conductive Member—

Conductive members of Examples 16 to 18 were produced in the same manner as in Example 1 except that the conductive layer was formed by applying and drying three coating fluids for forming a conductive layer obtained by mixing the above-described silver nanowire solvent-dispersed substance and the above-described photoresist compositions (1), (2), and (3) so that the mass ratio between the silver nanowires and the solid content amount of the photoresist composition became 1:2 using a slot die coater so that the silver amount reached 0.017 g/m².

Furthermore, in Comparative Example 1, conductive members of Comparative Examples 11 to 13 were produced in the same manner as in Comparative Example 1 except that the above-described three coating fluids for forming a conductive layer were used.

<Patterning>

A patterning treatment through photolithography was carried out on the above-obtained conductive members using the following method.

<Exposure Step>

The conductive layer on the substrate was exposed at an exposure amount of 40 mJ/cm² using an i-ray (365 nm) from an ultrahigh-pressure mercury lamp under a nitrogen atmosphere. Here, the exposure was carried out using a mask, and the mask had a conductive property, optical characteristics, a uniformly-exposed portion for film strength evaluation, and a stripe pattern (line/space=50 μm/50 μm) for patternability evaluation.

<Development Step>

The exposed conductive layer was shower-developed at 20° C. and a conic nozzle pressure of 0.15 MPa for 30 seconds using a sodium carbonate-based developing liquid (containing 0.06 mol/liter of sodium hydrogen carbonate, the same concentration of sodium carbonate, 1% sodium dibutyl naphthalene sulfonate, an anionic surfactant, a defoamer, and a stabilizer, product name: T-CD1, manufactured by FujiFilm Corporation) so as to remove the conductive layer in non-exposed portions, and the conductive layer was dried at room temperature. Next, a thermal treatment was carried out at 100° C. for 15 minutes. Therefore, a conductive layer including a conductive region and a non-conductive region was formed.

For the obtained conductive members, the surface resistance values A and B of the conductive layers on the A surface and the B surface and the A/B ratios were evaluated in the same manner as in Example 1, and the evaluation results were described in Table 4.

TABLE 4

| | | Evaluation result | | |
|---|---|---|---|---|
| | | | | Ratio of surface |
| | | Evaluation rank | | resistance value |
| | | of surface | | between front |
| Example/ | | resistance value | | surface and |
| Comparative | | A | B | back surface |
| Example | Materials used for matrix | surface | surface | A/B |
| Example 16 | Binder (A-1)/TAS-200 = 4.19/0.95/0.80 | 3 | 4 | 1.16 |
| Example 17 | Binder (A-1)/KAYARAD | 3 | 4 | 1.13 |
| | DPHA/IRGACURE379 = 3.80/1.59/0.159 | | | |
| Example 18 | Binder (A-1)/2-ethylhexyl | 3 | 4 | 1.15 |
| | acrylate/trimethylol phosphate | | | |
| | triacrylatc/IRGACURE379 = | | | |
| | 4.50/1.00/1.00/0.20 | | | |
| Example 19 | Binder (P-1) | 3 | 4 | 1.18 |
| Comparative | Binder (A-1)/TAS-200-4.19/0.95/0.80 | 2 | 4 | >1.5 |
| Example 11 | | | | |
| Comparative | Binder (A-1)/KAYARAD | 2 | 4 | >1.5 |
| Example 12 | DPHA/IRGACURE379 = 3.80/1.59/0.159 | | | |
| Comparative | Binder (A-1)/2-ethylhexyl | 2 | 4 | >1.5 |
| Example 13 | acrylate/trimethylol phosphate | | | |
| | triacrylate/IRGACURE379 = | | | |
| | 4.50/1.00/1.00/0.20 | | | |
| Comparative | Binder (P-1) | 2 | 4 | >1.5 |
| Example 14 | | | | |

From the results in Table 4, it is found that the same results are obtained even when the types of the matrix in the conductive layer are changed.

### Examples 20 and 21 and Comparative Examples 15 and 16

Conductive members were obtained in the same manner as in Example 1 or Comparative Example 1 except that the “silver nanowire dispersion liquid (2)” or the “silver nanowire dispersion liquid (3)” was used instead of the “silver nanowire dispersion liquid (1)”. For the obtained conductive members, the surface resistance values of the conductive layers on both surfaces and the A/B ratios were evaluated in the same manner as in Example 1, and the evaluation results were described in Table 5.

TABLE 5

| | Silver nanowires used for coating fluid for | | | Evaluation result | | |
|---|---|---|---|---|---|---|
| | forming conductive layer | | | | | Ratio of surface |
| | | Average major | Average minor | Evaluation | | resistance value |
| | | axis length of | axis length of | rank of surface | | between front surface |
| | Dispersion | silver nanowires | silver nanowires | resistance value | | and back surface |
| | liquid | (μm) | (nm) | A surface | B surface | A/B |
| Example 20 | (2) | 12.6 | 47.2 | 3 | 4 | 1.11 |
| Example 21 | (3) | 16 | 29 | 3 | 4 | 1.15 |
| Comparative | (2) | 12.6 | 47.2 | 3 | 4 | 1.4 |
| Example 15 | | | | | | |
| Comparative | (3) | 16 | 29 | 3 | 4 | 1.8 |
| Example 16 | | | | | | |

From the results in Table 5, it is found that the ratio A/B of the surface resistance value between the front surface and the back surface is likely to increases when the silver nanowires having a smaller average minor axis length are used; however, in the case of the conductive member according to the invention, the ratio A/B becomes less than 1.2.

What is claimed is:

1. A conductive member comprising:
a substrate;
conductive layers being provided on both surfaces of the substrate, and containing a conductive fiber having an average minor axis length of 150 nm or less and a matrix; and
intermediate layers being provided between the substrate and the conductive layers, and containing a compound having a functional group capable of interacting with the conductive fiber,
wherein, when surface resistance values of the two conductive layers are represented by A and B respectively, and an A value is equal to or greater than a B value, A/B is in a range of 1.0 to 1.2.

2. The conductive member according to claim 1, wherein the conductive fiber is a nanowire containing silver.

3. The conductive member according to claim 1, wherein the average minor axis length of the conductive fiber is 30 nm or less.

4. The conductive member according to claim 1,
wherein the matrix contains at least one selected from the group consisting of organic polymers, substances configured by including a three-dimensional crosslinking structure having a bond represented by the following general formula (I), and photoresist compositions,
-M¹-O-M¹- (I)
in the general formula (I), M¹ represents an element selected from the group consisting of Si, Ti, Zr, and Al.

5. The conductive member according to claim 1,
wherein the matrix is configured by including a three-dimensional crosslinking structure having a bond represented by the following general formula (I),
-M¹-O-M¹- (I)
in the general formula (I), M¹ represents an element selected from the group consisting of Si, Ti, Zr, and Al.

6. The conductive member according to claim 1, wherein the intermediate layers contain a compound having an amino group or an epoxy group.

7. The conductive member according to claim 1, wherein at least one of the two conductive layers provided on both surfaces of the substrate is configured by including a conductive region and a non-conductive region, and at least the conductive region contains the conductive fiber.

8. The conductive member according to claim 1, wherein the two conductive layers provided on both surfaces of the substrate are configured by including a conductive region and a non-conductive region respectively, and, when surface resistance values of the two conductive regions provided on both surfaces are represented by A and B respectively, and an A value is equal to or greater than a B value, A/B is in a range of 1.0 to 1.2.

9. A method for manufacturing a conductive member, comprising:
forming a first intermediate layer on a first surface of a substrate by applying a coating fluid for forming an intermediate layer containing a compound having a functional group capable of interacting with a conductive fiber to form a coated film, and drying the coated film;
forming a first conductive layer on the first intermediate layer by applying a coating fluid for forming a conductive layer containing a conductive fiber having an average minor axis length of 150 nm or less and at least one selected from the group consisting of organic polymers and photoresist compositions to form a coated film, and drying the coated film through heating;
forming a second intermediate layer on a second surface of the substrate by applying a coating fluid for forming an intermediate layer containing a compound having a functional group capable of interacting with a conductive fiber to form a coated film, and drying the coated film; and
forming a second conductive layer on the second intermediate layer by applying a coating fluid for forming a conductive layer containing a conductive fiber having an average minor axis length of 150 nm or less and at least one selected from the group consisting of organic polymers and photoresist compositions to form a coated film, and drying the coated film through heating,
wherein, when surface resistance values of the first conductive layer and the second conductive layer are represented by A and B respectively, and an A value is equal to or greater than a B value, A/B is in a range of 1.0 to 1.2.

10. A method for manufacturing a conductive member, comprising:
forming a first intermediate layer on a first surface of a substrate by applying a coating fluid for forming an intermediate layer containing a compound having a functional group capable of interacting with a conductive fiber to form a coated film, and drying the coated film;
forming a first conductive layer on the first intermediate layer by applying a coating fluid for forming a conductive layer containing a conductive fiber having an average minor axis length of 150 nm or less and at least one alkoxide compound of an element selected from the group consisting of Si, Ti, Zr, and Al to form a coated film, hydrolyzing and polycondensing the alkoxide compound in the coated film through heating the coated film to form a three-dimensional crosslinking structure having a bond represented by the following general formula (I) in the coated film,
forming a second intermediate layer on a second surface of the substrate by applying a coating fluid for forming an intermediate layer containing a compound having a functional group capable of interacting with a conductive fiber to form a coated film, and drying the coated film; and
forming a second conductive layer on the second intermediate layer by applying a coating fluid for forming a conductive layer containing a conductive fiber having an average minor axis length of 150 nm or less and at least one alkoxide compound of an element selected from the group consisting of Si, Ti, Zr, and Al to form a coated film, hydrolyzing and polycondensing the alkoxide compound in the coated film through heating the coated film to form a three-dimensional crosslinking structure having the bond represented by the following general formula (I) in the coated film;
wherein, when surface resistance values of the first conductive layer and the second conductive layer are represented by A and B respectively, and an A value is equal to or greater than a B value, A/B is in a range of 1.0 to 1.2,
-M¹-O-M¹- (I)
in the general formula (I), M¹ represents an element selected from the group consisting of Si, Ti, Zr, and Al.

11. The method for manufacturing a conductive member according to claim 9, comprising: carrying out a surface treatment on the first surface and the second surface of the substrate before forming the first intermediate layer.

12. The method for manufacturing a conductive member according to claim 10, comprising: carrying out a surface treatment on the first surface and the second surface of the substrate before forming the first intermediate layer.

13. The method for manufacturing a conductive member according to claim 11, wherein at least one of a condition that a temperature of the coated film when the coated film is dried in forming the first intermediate layer is a temperature lower than a temperature of the coated film when the coated film is dried in forming the second intermediate layer by 20° C. or more and a condition that a temperature of the coated film during the heating in forming the first conductive layer is a temperature lower than a temperature of the coated film during the heating in forming the second conductive layer by 20° C. or more is satisfied.

14. The method for manufacturing a conductive member according to claim 12, wherein at least one of a condition that a temperature of the coated film when the coated film is dried in forming the first intermediate layer is a temperature lower than a temperature of the coated film when the coated film is dried in forming the second intermediate layer by 20° C. or more and a condition that a temperature of the coated film during the heating in forming the first conductive layer is a temperature lower than a temperature of the coated film during the heating in forming the second conductive layer by 20° C. or more is satisfied.

15. The method for manufacturing a conductive member according to claim 11, wherein a solid content application amount of the coating fluid for forming the intermediate layer in forming the second intermediate layer is in a range of two to three times of a solid content application amount of the coating fluid for forming the intermediate layer in forming the first intermediate layer.

16. The method for manufacturing a conductive member according to claim 12, wherein a solid content application amount of the coating fluid for forming the intermediate layer in forming the second intermediate layer is in a range of two to three times of a solid content application amount of the coating fluid for forming the intermediate layer in forming the first intermediate layer.

17. The method for manufacturing a conductive member according to claim 11, wherein the surface treatment is a corona discharging treatment, a plasma treatment, a glow treatment, or an ultraviolet ozone treatment, and a treatment amount for treating the second surface of the substrate is in a range of two to six times of a treatment amount for treating the first surface of the substrate.

18. The method for manufacturing a conductive member according to claim 12, wherein the surface treatment is a corona discharging treatment, a plasma treatment, a glow treatment, or an ultraviolet ozone treatment, and a treatment amount for treating the second surface of the substrate is in a range of two to six times of a treatment amount for treating the first surface of the substrate.

19. The method for manufacturing a conductive member according to claim 9, further comprising: forming a conductive region and a non-conductive region in at least one of the first conductive layer and the second conductive layer.

20. The method for manufacturing a conductive member according to claim 10, further comprising: forming a conductive region and a non-conductive region in at least one of the first conductive layer and the second conductive layer.

21. A touch panel comprising: the conductive member according to claim 1, wherein a thickness of the conductive member is in a range of 30 μm to 200 μm.
